(19) United States
(12) Patent Application Publication
(10) Pub. No.: US 2023/0408922 A1
(43) Pub. Date: Dec. 21, 2023

(54) APPLICATION LIQUID FOR OPTICAL MEMBER, POLYMER, PHOTOSENSITIVE APPLICATION LIQUID, METHOD FOR PRODUCING CURED FILM, METHOD FOR PRODUCING PATTERNED CURED FILM, AND METHOD FOR PRODUCING POLYMER

(71) Applicant: CENTRAL GLASS COMPANY, LIMITED, Ube-shi (JP)

(72) Inventors: Yuri OIKAWA, Saitama (JP); Takashi MASUBUCHI, Saitama (JP); Kazuhiro YAMANAKA, Saitama (JP); Rikako YOTSUMOTO, Saitama (JP)

(21) Appl. No.: 18/334,118

(22) Filed: Jun. 13, 2023

Related U.S. Application Data
(63) Continuation of application No. PCT/JP2021/046166, filed on Dec. 15, 2020.

(30) Foreign Application Priority Data
Dec. 15, 2020 (JP) 2020-207818

(51) Int. Cl. G03F 7/075; C08G 77/24; C08K 3/22; C08K 3/36

(52) U.S. Cl. CPC G03F 7/0757; C08G 77/24; C08K 3/22; C08K 3/36; C08K 2003/2241; C08K 2003/2244

(57) ABSTRACT

An application liquid for an optical member comprises a component (A) consisting of metal fine particles (A-1) and/or a metal compound (A-2) including a constituent unit represented by the following general formula (1-A), a stabilizer (B) consisting of a polysiloxane compound including a constituent unit represented by the following general formula (1); and a solvent (C),

[(R¹)_{b}MO_{c/2}] (1-A)

[(R²)_{d}(R³)ₑ(OR⁴)_{f}SiO_{g/2}] (1)

### CROSS-REFERENCE TO RELATED APPLICATIONS

This application is a Continuation of International Patent Application No. PCT/JP2021/046166, filed on Dec. 15, 2021, which claims the benefit of priority to Japanese Patent Application No. 2020-207818, filed on Dec. 15, 2020, the entire contents of which are incorporated herein by reference.

### FIELD

The present disclosure relates to an application liquid for an optical member, a polymer, a cured film, a photosensitive application liquid, a patterned cured film, an optical member, a solid-state image sensor, a display device, a polysiloxane compound, a stabilizer for use in an application liquid, a method for producing the cured film, a method for producing the patterned cured film, and a method for the producing polymer.

### BACKGROUND

Polymer compounds containing siloxane bonds (hereinafter sometimes referred to as polysiloxane) are used as coating materials for liquid crystal displays and organic EL displays, coating materials for image sensors, and sealing materials in the field of semiconductors, taking advantage of their high heat resistance and transparency and the like. For example, Japanese laid-open patent publication No. 2015-117277 describes a coating material for forming a high-refractive-index inorganic planarizing layer, containing two kinds of inorganic oxide fine particles having at least one selected from a group consisting of TiO₂ and ZrO₂ as a main component and having different major diameter/minor diameter ratios and average particle diameters, a silica oligomer composed of a hydrolysis product of alkoxysilane, and a high-boiling-point solvent.

On the other hand, Japanese laid-open patent publication No. 2015-193757 describes a method for producing a coating composition for forming a hard coat layer, which includes a step of preparing a dispersion liquid including crystalline inorganic oxide fine particles having an average particle diameter in the range of 5 to 50 nm and containing one or two or more kinds of metal components selected from Ti, Zn, Sn, and Zr, a polymerizable organosilicon compound, a curing catalyst, and a dispersion medium, and a step of volatilizing and removing all or part of the dispersion medium from the dispersion liquid to obtain a coating composition having a viscosity of 10 to 40 mPa-s, in order to form a hard coat layer which is thick and has excellent scratch resistance, transparency and weatherable adhesion.

In addition, International patent publication No. 2016/051718 describes solid spherical silica fine particles containing silica fine particles having an average particle diameter of 200 to 600 nm as silica fine particles in a low-reflection coating fixed by a binder containing a metal oxide as a main component, the binder contains silica as a metal oxide, and the transmittance gain obtained by applying a low-reflection coating to a substrate is 1.5% or more.

### SUMMARY

As described in Japanese laid-open patent publication No. 2015-117277, Japanese laid-open patent publication No. 2015-193757, and International patent publication No. 2016/051718, in order to obtain an optical member having a predetermined refractive index, an application liquid in which metal fine particles are dispersed in a polymer of a metal compound needs to be used. However, there is a problem in that the metal fine particles tend to settle in the application liquid, and there is a problem in maintaining the stability of the application liquid.

In order to obtain an optical member having excellent optical properties, the application liquid needs to be stable. An embodiment of the present invention provides an application liquid for an optical member in which metal fine particles are stably dispersed in an application liquid. Alternatively, in an embodiment, an application liquid is provided in which sedimentation or precipitation of a metal alkoxide is unlikely to occur. Alternatively, in an embodiment, a polymer is provided that can be used as an application liquid for an optical member, a cured film using the application liquid for an optical member, a photosensitive application liquid, a patterned cured film, an optical member, a solid-state image sensor, a display device, and a stabilizer for use in an application liquid. Alternatively, a method for producing a stabilizer for use in an application liquid is provided. Alternatively, a method for producing a cured film, a patterned cured film, or a polymer having excellent optical properties is provided.

As a result of intensive studies to solve the above problems, an application liquid for an optical member containing a component (A) consisting of metal fine particles (A-1) and/or a metal compound (A-2) including a constituent unit represented by the following general formula (1-A), a stabilizer (B) consisting of a polysiloxane compound including a constituent unit represented by the following general formula (1), and a solvent (C) was found.

[(R¹)_{b}MO_{c/2}] (1-A)

[(R²)_{d}(R³)ₑ(OR⁴)_{f}SiO_{g/2}] (1)

In the general formula (1-A), M is at least one selected from a group consisting of Ti, Zr, Al, Hf, In, and Sn, each R¹ is independently selected from a group consisting of a hydrogen atom, hydroxyl group, halogen group, alkoxy group having a carbon number of 1 or more and 5 or less, an alkyl group having a carbon number of 1 or more and 5 or less, a phenyl group, and a fluoroalkyl group having a carbon number of 1 or more and 10 or less. b is a number of 0 or more and less than 4, c is a number more than 0 and 4 or less, and b+c=3 or 4. In the general formula (1), R² is a group represented by the following general formula (1a).

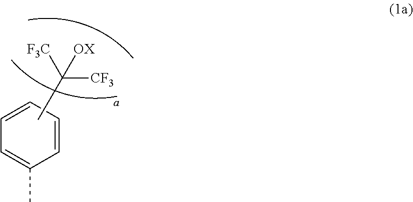

In the general formula (1a), X is a hydrogen atom or an acid-labile group. a is a number of 1 to 5, and a broken line represents a bond. Each R³ is independently selected from a group consisting of a hydrogen atom, an alkyl group having a carbon number of 1 or more and 5 or less, a phenyl group, and a fluoroalkyl group having a carbon number of 1 or more and 10 or less, and each R⁴ is independently selected from a group consisting of a hydrogen atom or an alkyl group having a carbon number of 1 or more and 5 or less. d is a number of 1 or more and 3 or less, e is a number of 0 or more and 2 or less, f is a number of 0 or more and less than 3, g is a number more than 0 and 3 or less, and d+e+f+g=4.

It is preferable that the metal fine particles (A-1) include at least one selected from a group consisting of Si, Ti, Zr, Al, Mg, Hf, In, and Sn. The metal fine particles (A-1) are preferably at least one selected from a group consisting of silica, hollow silica, titanium oxide, zirconium oxide, magnesium fluoride, indium tin oxide, antimony-doped indium oxide, and hafnium oxide.

In addition, the group represented by the general formula (1a) is preferably a group represented by any of the following general formulas (1aa) to (1ad).

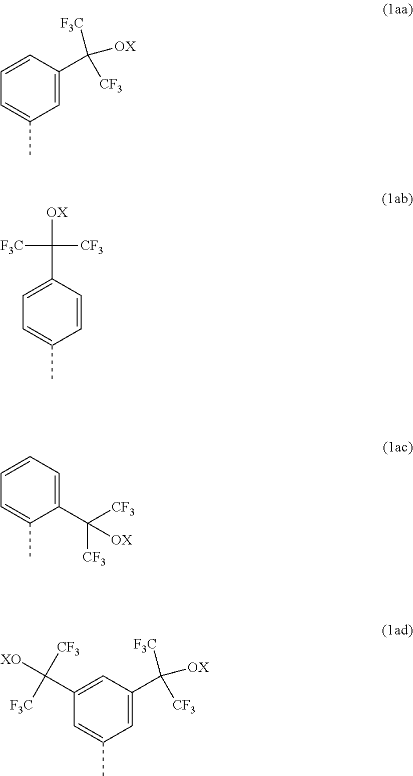

In the general formulas (1aa) to (1ad), the definitions of X and the broken line are the same as the definitions in the general formula (1a).

The polysiloxane compound preferably includes a constituent unit represented by the following general formula (2) and/or the following general formula (3).

[(R⁵)ₕ(R⁶)ᵢSiO_{j/2}] (2)

[(R⁷)ₖSiO_{l/2}] (3)

In the general formula (2), R⁵ is a substituent selected from monovalent organic groups having a carbon number of 1 or more and 30 or less substituted by any of an epoxy group, oxetane group, acryloyl group, methacryloyl group, and a lactone group. R⁶ is a hydrogen atom, or a substituent selected from the group consisting of, a halogen group, an alkyl group having a carbon number of 1 or more and 5 or less, a phenyl group, hydroxy group, an alkoxy group having a carbon number of 1 or more and 3 or less, and a fluoroalkyl group having a carbon number of 1 or more and 10 or less. h is a number of 1 or more and 3 or less, i is a number of 0 or more and less than 3, j is a number more than 0 and 3 or less, and h+l+j=4. When there is a plurality of R⁵ and R⁶, each of them is independently selected from any of the substituents described above. In the general formula (3), R⁷ is a substituent selected from a group consisting of a halogen group, alkoxy group, and a hydroxy group. k is a number of 0 or more and less than 4, l is a number more than 0 and 4 or less, and k+l=4.

The monovalent organic group R⁵ is preferably a group represented by any of the following general formulas (2a), (2b), (2c), (3a), and (4a).

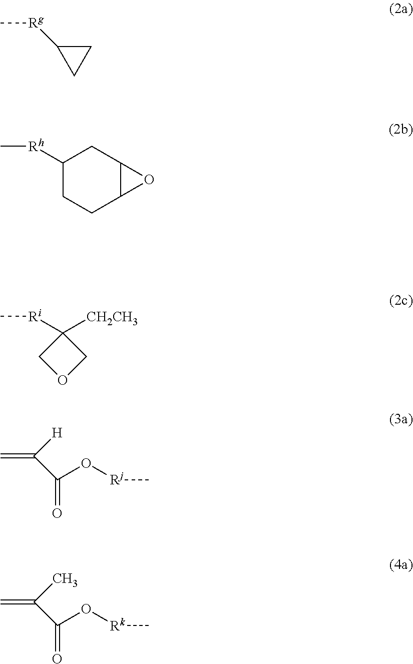

In the general formulas (2a), (2b), and (2c), each R^{g}, R^{h}, Rⁱ is independently a divalent linking group, and a broken line represents a bond. In the general formulas (3a) and (4a), each R^{j} and R^{k} is independently a divalent linking group, and a broken line represents a bond.

The constituent unit represented by the general formula (3) preferably contains less than 5 mol % or more than 50 mol % in the whole constituent unit of the polysiloxane compound represented by the general formula (1).

The solvent (C) preferably includes at least one compound selected from a group consisting of propylene glycol monomethyl ether acetate, propylene glycol monomethyl ether, cyclohexanone, ethyl lactate, γ-butyrolactone, diacetone alcohol, diglyme, methyl isobutyl ketone, 3-methoxybutyl acetate, 2-heptanone, N,N-dimethylformamide, N,N-dimethylacetamide, N-methylpyrrolidone, glycols, glycol ethers and glycol ether esters.

### BRIEF DESCRIPTION OF DRAWINGS

FIG. 1 is a schematic view illustrating a method for producing a patterned cured film according to an embodiment of the present invention.

### DESCRIPTION OF EMBODIMENTS

Hereinafter, an application liquid for an optical member, a polymer, a cured film, a photosensitive application liquid, a patterned cured film, an optical member, a solid-state image sensor, a display device, a polysiloxane compound, a stabilizer used in the application liquid, a method for producing a cured film, a method for producing a patterned cured film, and a method for producing a polymer according to an embodiment of the present disclosure will be described. However, the embodiments of the present invention are not to be construed as being limited to the descriptions of the embodiments and examples described below. In the present specification, the expression “Xa to Ya” in describing a numerical value range means Xa or more and Ya or less unless otherwise specified.

As a result of intensive studies to solve the above problems, the present inventors have found that an application liquid and a photosensitive application liquid can be obtained in which a hexafluoroisopropanol (HFIP) group contained in a polysiloxane compound represented by the general formula (1) increases the content of a component (A) for achieving a predetermined refractive index like metal fine particles (component (A-1) described later) such as silica, hollow silica, titanium oxide, zirconium oxide, magnesium fluoride, ITO, ATO, and hafnium oxide or a hydrolyzed polycondensate of Ti, Zr, Hf, In, Sn, and the like (component (A-2) described later), and precipitation derived from a raw material represented by the metal fine particles and/or the hydrolysis condensate is suppressed. The increase in the content of the component (A) and the suppression of precipitation derived from the raw material are presumed to be due to the fact that the HFIP group contained in the polysiloxane compound represented by the general formula (1), that is, the component (B) enhances compatibility with the component (A). That is, the present inventors have found that a polysiloxane compound including a constituent unit represented by the general formula (1) serves as a stabilizer for suppressing sedimentation derived from the raw material such as metal fine particles and/or hydrolysis condensates in the application liquid. Further, it has been found that curing the application liquid according to an embodiment of the present invention makes it possible to obtain a uniform permanent structure (which refers to a cured film, a patterned cured film, or the like, which is an embodiment of the present invention) that can be adjusted to a range less than 1.44 and more than 1.54 in the numerical range of the refractive index.

In the present specification, “suppressing sedimentation” refers to a state in which a sediment and/or a precipitate derived from a raw material (for example, component (A)) cannot be visually confirmed in the application liquid or the photosensitive application liquid. In the present specification, a state in which sedimentation is suppressed may be referred to as “dispersion”.

For example, in the case where the component (A) is the metal fine particles (A-1), “dispersion” may refer to a condition in which aggregation is excessive to the extent that it causes sedimentation is suppressed. In the case where the component (A) is a hydrolyzed polycondensate (A-2), “dispersion” may refer to a condition captured in the network through an interaction (for example, a copolymerization reaction) with another component contained in the application liquid or the photosensitive application liquid.

In an embodiment, the application liquid for an optical member includes the following component (A), a stabilizer (B), and a solvent (C).

### [Component (A)]

The component (A) consists of metal fine particles (A-1) and/or a metal compound (A-2) including a constituent unit represented by the following general formula (1-A).

### [Metal Fine Particles (A-1)]

In an embodiment, the metal fine particles (A-1) may include at least one selected from a group consisting of Si, Ti, Zr, Al, Mg, Hf, In, and Sn. In an embodiment, the metal fine particles (A-1) may be fine particles composed of a single metal or fine particles of a metal compound. The fine particles of the metal compound may be fine particles of a metal oxide or fine particles of a metal halide. Specifically, in an embodiment, the metal fine particles (A-1) may be at least one selected from a group consisting of silica, hollow silica, titanium oxide, zirconium oxide, magnesium fluoride, indium tin oxide, antimony-doped indium oxide, and hafnium oxide. In addition, the metal fine particles (A-1) may be surface-treated by a known method in order to suppress aggregation or improve dispersibility.

Among the metal fine particles described above, hollow silica is particularly preferable as the fine particles for reducing the refractive index of the cured film and the patterned cured film, and titanium oxide and zirconium oxide are particularly preferable as the fine particles for increasing the refractive index. In addition, “reduced refractive index” may refer to a refractive index of less than 1.44 as described above. “High refractive index” may refer to a refractive index of more than 1.54 as described above.

Examples of commercially available hollow silica particles include THRULYA and OSCAL manufactured by JGC Catalysts and Chemicals Ltd., SNOWTEX manufactured by Nissan Chemical Corporation, Quartron manufactured by FUSO CHEMICAL CO., LTD., and the like.

Examples of commercially available titanium oxide particles may be any of a rutile type and an anatase type, and examples thereof include SRD series and SAD series manufactured by Sakai Chemical Industry Co., Ltd., TIPAQUE manufactured by ISHIHARA SANGYO KAISHA, LTD., KRONOS manufactured by Titan Kogyo, Ltd., TITANIX manufactured by TAYCA CORPORATION, Ti-Pure manufactured by DuPont de Nemours, Inc., and OPTOLAKE and ELCOM manufactured by JGC Catalysts and Chemicals Ltd.

Examples of commercially available zirconium oxide particles include SZR series manufactured by Sakai Chemical Industry Co., Ltd., and ZIRCONEO manufactured by ITEC Co., Ltd.

The particle diameter of the metal fine particles (A-1) is not particularly limited as long as the cured film or the patterned cured film including the metal fine particles has a visible-light transmittance that can be used as an optical member. In the present specification, the particle diameter may be a value obtained by a measurement method, and the shape thereof may be a primary particle or a secondary particle.

For example, the cumulative 50% diameter (hereinafter, sometimes referred to as “D₅₀”) measured by a light-scattering liquid borne particle counting method using a laser as a light source is preferably 1 nm to 200 nm because a good visible-light transmittance can be obtained. In addition, a commercially available measuring device capable of measuring the diameter of the metal fine particles may be used for the D₅₀. In the present specification, for example, a measuring device (for example, HORIBA SZ-100) to which a photon correlation method is applied and a measuring device (for example, HORIBA LA-960 and HORIBA LA-350) to which a laser diffraction scattering method is applied can be appropriately selected and measured according to respective measurable ranges. For example, the measuring device to which the photon correlation method is applied may be used when the particle diameter to be measured is less than 1 μm, and the measuring device to which the laser diffraction scattering method is applied may be used when the particle diameter to be measured is 1 μm or more.

The content of the metal fine particles (A-1) may be appropriately selected depending on the application of the optical member. For example, when the total of the component (A) and the component (B) is 100% by mass, the component (A-1) is preferably 1% by mass to 90% by mass because it can be adjusted to a desired refractive index when forming a cured film or a patterned cured film or it has a visible-light transmittance that can be used as an optical member. More preferably it may be 10% by mass to 80% by mass.

### [Metal Compound (A-2)]

The metal compound (A-2) is a metal compound including a constituent unit represented by the following general formula (1-A).

[(R¹)_{b}MO_{c/2}] (1-A)

In the general formula (1-A), M is at least one selected from a group consisting of Ti, Zr, Al, Hf, In, and Sn, each R₁ is independently selected from a group consisting of a hydrogen atom, hydroxyl group, halogen group, an alkoxy group having a carbon number of 1 or more and 5 or less, an alkyl group having a carbon number of 1 or more and 5 or less, a phenyl group, and a fluoroalkyl group having a carbon number of 1 or more and 10 or less. b is a number of 0 or more and less than 4, c is a number more than 0 and 4 or less, and b+c=3 or 4.

In this case, in the constituent unit represented by the general formula (1-A), as theoretical values of b and c are, b is an integer of 0 to 4, and c is an integer of 0 to 4. In addition, b+c=3 or 4 means that the sum of the theoretical values is 3 or 4. However, for example, in the value obtained by a polynuclear NMR measurement capable of measuring Ti, Zr, Al, Hf, In, Sn, or the like, each of b and c is obtained as an average value, so that b of the average value may be a decimal that would be 0 or more and 4 or less when rounded (where b<4.0), and c may be a decimal that would be 0 or more and 4 or less when rounded (where c≠0). In addition, the theoretical value c=0 indicates that the constituent unit is a monomer, and the average value c≠0 indicates that all of the compounds are not monomers. Therefore, the description that c is an integer of 0 to 4 as a theoretical value and c is a decimal that would be 0 or more and 4 or less when rounded (where c≠0) as a value obtained by measuring the polynuclear NMR indicates that a compound including a constituent unit represented by the general formula (1-A) may contain a monomer, but not all of the constituent units are monomers.

The constituent unit represented by the general formula (1-A) are preferably such that M is Ti, Zr, R¹ is a hydroxyl group, halogen group, an alkoxy group having a carbon number of 1 or more and 5 or less, an alkyl group having a carbon number of 1 or more and 5 or less, or a phenyl group.

The content of the metal compound (A-2) may be appropriately selected depending on the application of the optical member. For example, when the total of the component (A) and the component (B) is 100% by mass, the component (A-2) is preferably 1% by mass to 90% by mass because it can be adjusted to a desired refractive index when forming a cured film or a patterned cured film or it has a visible-light transmittance that can be used as an optical member. More preferably it may be 10% by mass to 80% by mass.

### [Stabilizer (B)]

The stabilizer (B) consists of a polysiloxane compound including a first constituent unit represented by the following general formula (1).

[(R²)_{d}(R³)ₑ(OR⁴)_{f}SiO_{g/2}] (1)

In the general formula (1), R² is a group represented by the following general formula (1a).

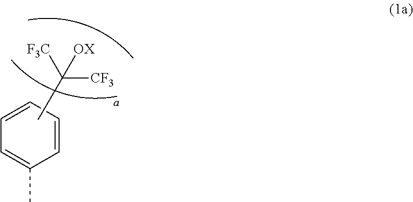

In the general formula (1a), X is a hydrogen atom or an acid-labile group.

a is a number of 1 to 5, and a broken line represents a bond.

Each R³ is independently selected from a group consisting of a hydrogen atom, an alkyl group having a carbon number of 1 or more and 5 or less, a phenyl group, and a fluoroalkyl group having a carbon number of 1 or more and 10 or less, and each R⁴ is independently selected from a group consisting of a hydrogen atom or an alkyl group having a carbon number of 1 or more and 5 or less.

d is a number of 1 or more and 3 or less, e is a number of 0 or more and 2 or less, f is a number of 0 or more and less than 3, g is a number more than 0 and 3 or less, and d+e+f+g=4.

In this case, in the first constituent unit represented by the general formula (1), as theoretical values of d, e, f, and g, d is an integer of 1 to 3, e is an integer of 0 to 2, f is an integer of 0 to 3, and g is an integer of 0 to 3. In addition, d+e+f+g=4 means that the sum of the theoretical values is 4. However, for example, in the value obtained by ²⁹Si NMR measurement, d may be a decimal that would be 1 or more and 3 or less when rounded, e may be a decimal that would be 0 or more and 2 or less when rounded, f may be a decimal that would be 0 or more and 2 or less when rounded (f<3.0), and g may be a decimal that would be 0 or more and 3 or less (g≠0). The description that g is an integer of 0 to 3 as the theoretical value and g is a decimal that would be 0 or more and 3 or less as a value obtained by ²⁹Si NMR measurement when rounded (where g≠0) indicates that the polysiloxane compound may contain a monomer, but not all of the constituent units are monomers.

In the monovalent group represented by the general formula (1a), a is an integer of 1 or more and 5 or less as a theoretical value. However, for example, the value obtained by ²⁹Si NMR measurement may be a decimal that would be 1 or more and 5 or less when rounded.

In an embodiment, a group represented by the general formula (1a) may be a group represented by any of the following formulas (1aa) to (1ad). In the general formulas (1aa) to (1ad), the definitions of X and the broken line are the same as the definitions in the general formula (1a).

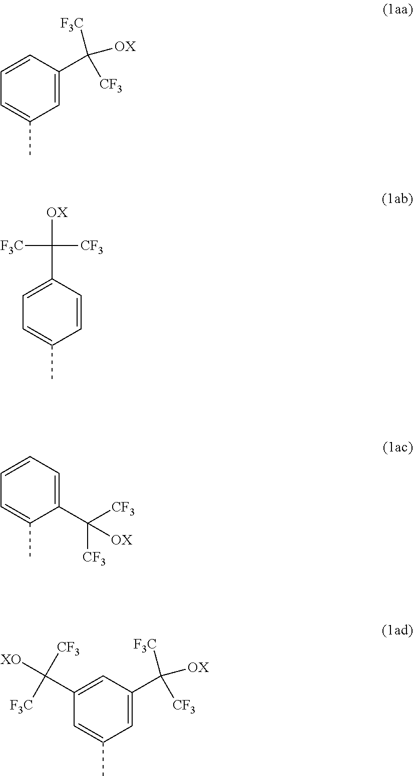

In an embodiment, the polysiloxane compound included as the stabilizer (B) may include a second constituent unit represented by the following general formula (2) and/or a third constituent unit represented by the following general formula (3).

[(R⁵)ₕ(R⁶)ᵢSiO_{j/2}] (2)

[(R⁷)ₖSiO_{l/2}] (3)

In the general formula (2), R⁵ is a substituent selected from monovalent organic groups having a carbon number of 1 or more and 30 or less substituted by any of an epoxy group, oxetane group, acryloyl group, methacryloyl group, and lactone group. R⁶ is a hydrogen atom, or a substituent selected from the group consisting of a halogen group, an alkyl group having a carbon number of 1 or more and 5 or less, a phenyl group, hydroxy group, an alkoxy group having a carbon number of 1 or more and 3 or less, and a fluoroalkyl group having a carbon number of 1 or more and 10 or less. h is a number of 1 or more and 3 or less, i is a number of 0 or more and less than 3, j is a number more than 0 and 3 or less, and h+l+j=4. In addition, when there is a plurality of R⁵ and R⁶, each of them is independently selected from any of the substituents described above.

In the general formula (3), R⁷ is a substituent selected from a group consisting of a halogen group, alkoxy group, and a hydroxy group. k is a number of 0 or more and less than 4, l is a number more than 0 and 4 or less, and k+l=4.

In this case, in the second constituent unit represented by the general formula (2), as theoretical values of h, i, and j, h is an integer of 1 to 3, i is an integer of 0 to 3, and j is an integer of 0 to 3. In addition, h+l+j=4 means that the sum of the theoretical values is 4. However, for example, in the values obtained by ²⁹Si NMR measurement, each of h, i, and j, is obtained as an average value, so that the average value h may be a decimal that would be 1 or more and 3 or less when rounded, i may be a decimal that would be 0 or more and 3 or less when rounded (where i<3.0), and j may be a decimal that would be 0 or more and 3 or less when rounded (where j≠0).

In the third constituent unit represented by the general formula (3), as theoretical values of k and l, k is an integer of 0 to 4, and l is an integer of 0 to 4. In addition, k+l=4 means that the sum of the theoretical values is 4. However, for example, in the value obtained by ²⁹Si NMR measurement, each of k and l is obtained as an average value, so that the average value k may be a decimal that would be 0 or more and 4 or less when rounded (where k<4.0), and l may be a decimal that would be 0 or more and 4 or less when rounded (where l≠0).

It is considered that including the polysiloxane compound including the first constituent unit represented by the general formula (1) makes it possible to realize an application liquid and a photosensitive application liquid in which the HFIP group enhances compatibility with the component (A) described above, increases the content of the component (A), and suppresses sedimentation of the component derived from the raw material such as the component (A).

In addition, O_{g/2} in the general formula (1) is generally used as a representation of the polysiloxane compound, and the following general formula (1-1) represents the case where g is 1, the general formula (1-2) represents the case where g is 2, and the general formula (1-3) represents the case where g is 3. In the case where g is 1, it is located at the end of the polysiloxane chain in the polysiloxane compound.

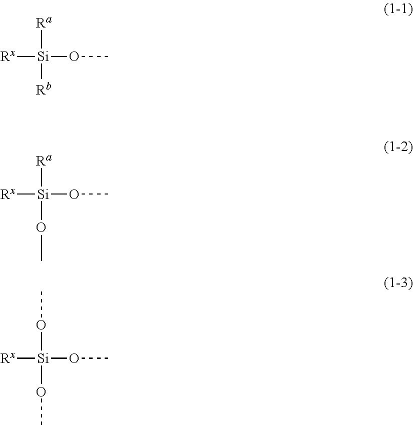

In the general formulas (1-1) to (1-3), R^{x} has the same meaning as R² in the general formula (1), and each R^{a}, R^{b} has the same meaning as R², R³, and OR⁴ in the general formula (1). The broken lines represent bonds with other Si atoms.

O_{j/2} in the general formula (2) is used as described above, and the following general formula (2-1) represents the case where j is 1, the general formula (2-2) represents the case where j is 2, and the general formula (2-3) represents the case where j is 3, as described above. In the case where j is 1, it is located at the end of the polysiloxane chain in the polysiloxane compound.

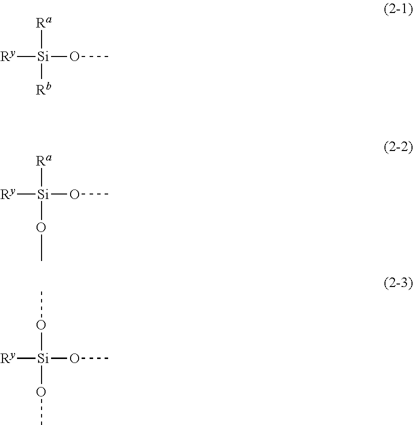

In general formulas (2-1) to (2-3), RV has the same meaning as R⁵ in the general formula (2), and each R^{a}, R^{b} has the same meaning as R⁵, R⁶ in the general formula (2). The broken lines represent bonds with other Si atoms.

For O_{l/2} in the general formula (3), O_{l/2} in the case where l=4 represents the following general formula (3-1). In the general formula (3-1), the broken lines represent bonds with other Si atoms.

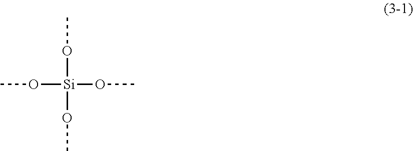

O_{4/2} in the above general formula (3) is generally called a Q4 unit, and shows a structure in which all four bonds of a Si atom form siloxane bonds. Although Q4 have been described above, the general formula (3) may contain a hydrolyzable and condensable group in the bond such as in Q0, Q1, Q2, and Q3 units shown below. In addition, the general formula (3) may have at least one selected from a group consisting of Q1 to Q4 units.

Q0 unit: a structure in which all four bonds of a Si atom are hydrolyzable and polycondensable groups (such as a halogen group, alkoxy group, or hydroxy group that can form siloxane bonds).

Q1 unit: a structure in which one of the four bonds of a Si atom forms a siloxane bond and the other three are all hydrolyzable and polycondensable groups.

Q2 unit: a structure in which two of the four bonds of a Si atom form a siloxane bond and the other two are all hydrolyzable and polycondensable groups.

Q3 unit: a structure in which three of the four bonds of a Si atom form a siloxane bond and the other one is the hydrolyzable and polycondensable group.

Hereinafter, the constituent unit represented by the general formula (1), the general formula (2), and the general formula (3) of the polysiloxane compound used as the stabilizer (B) will be described in order.

### [Constituent Unit Represented by the General Formula (1)]

[(R²)_{d}(R³)ₑ(OR⁴)_{f}SiO_{g/2}] (1)

In the general formula (1), R² is a group represented by the following general formula (1a).

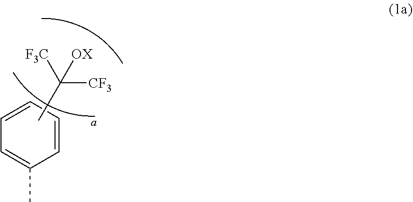

In the general formula (1a), X is a hydrogen atom or an acid-labile group.

A is a number of 1 to 5, and a broken line represents a bond.

In this case, the acid-labile group is a group that is eliminated by the action of an acid and may contain an oxygen atom, a carbonyl bond, or a fluorine atom in part thereof.

A photoinduced compound containing a photoacid generator or a group capable of causing elimination by an effect such as hydrolysis can be used as the acid-labile group without any particular limitation, and examples thereof include an alkyl group, alkoxycarbonyl group, acetal group, silyl group, and an acyl group.

Examples of the alkyl group include tert-butyl group, tert-amyl group, 1,1-dimethylpropyl group, 1-ethyl-1-methylpropyl group, 1,1-dimethylbutyl group, allyl group, 1-pyrenylmethyl group, 5-dibenzosuberyl group, triphenylmethyl group, 1-ethyl-1-methylbutyl group, 1,1-diethylpropyl group, 1,1-dimethyl-1-phenylmethyl group, 1-methyl-1-ethyl-1-phenymethyl group, 1,1-diethyl-1-phenylmethyl group, 1-methylcyclohexyl group, 1-ethylcyclohexyl group, 1-methycyclopentyl group, 1-ethylcyclopentyl group, 1-isobornyl group, 1-methyladamantyl group, 1-ethyladamantyl group, 1-isopropyladamantyl group, 1-isopropylnorbornyl group, and 1-isopropyl-(4-methylcyclohexyl) group, and the like. The alkyl group is preferably a tertiary alkyl group, more preferably a group represented by —CR^{q}R^{q}R^{r} (R^{p}, R^{a}, and R^{r} are each independently a linear or branched alkyl group, a monocyclic or polycyclic cycloalkyl group, an aryl group or an aralkyl group, and two of R^{p}, R^{q}, and R^{r} may be bonded to form a ring structure).

Examples of the alkoxycarbonyl group include tert-butoxycarbonyl group, tert-amyloxycarbonyl group, methoxycarbonyl group, ethoxycarbonyl group, and i-propoxycarbonyl group. The acetal group includes methoxymethyl group, ethoxyethyl group, butoxyethyl group, cyclohexyloxyethyl group, benzyloxyethyl group, phenethyloxyethyl group, ethoxypropyl group, benzyloxypropyl group, phenethyloxypropyl group, ethoxybutyl group, ethoxyisobutyl group, and the like.

Examples of the silyl group include trimethylsilyl group, ethyldimethylsilyl group, methydiethylsilyl group, triethylsilyl group, i-propyldimethylsilyl group, methyldi-i-propylsilyl group, tri-i-propylsilyl group, t-butyldimethylsilyl group, methyldi-t-butylsilyl group, tri-t-butylsilyl group, phenyldimethylsilyl group, methyldiphenylsilyl group, triphenylsilyl group, and the like.

Examples of the acyl group include acetyl group, propionyl group, butyryl group, heptanoyl group, hexanoyl group, valeryl group, pivaloyl group, isovaleryl group, lauroyl group, myristoyl group, palmitoyl group, stearoyl group, oxalyl group, malonyl group, succinyl group, glutaryl group, adipoyl group, pimeloyl group, suberoyl group, azelaoyl group, sebacoyl group, acryloyl group, propioloyl group, methacryloyl group, crotonoyl group, oleoyl group, maleoyl group, fumaroyl group, mesaconoyl group, camphoroyl group, benzoyl group, phthaloyl group, isophthaloyl group, terephthaloyl group, naphthoyl group, toluoyl group, hydroatropoyl group, atropoyl group, cinnamoyl group, furoyl group, tenoyl group, nicotinoyl group, isonicotinoyl group, and the like.

Among them, tert-butoxycarbonyl group, methoxymethyl group, ethoxyethyl group, and trimethylsilyl group are generally preferable. Furthermore, it is also possible to use those in which part or all of the hydrogen atoms of these acid-labile groups are substituted with fluorine atoms. These acid-labile groups may be used in a single type or in a plurality of types.

Particularly preferred structures of the acid-labile group include a structure represented by the following general formula (ALG-1) and a structure represented by the following general formula (ALG-2).

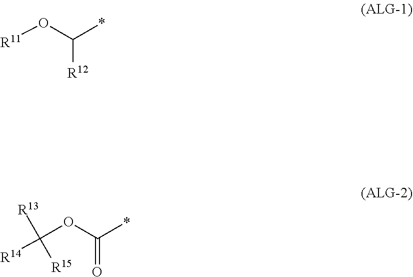

In the general formula (ALG-1) and the general formula (ALG-2), R¹¹ is a linear alkyl group having a carbon number of 1 to 10, a branched alkyl group having a carbon number of 3 to 10 or cyclic alkyl group having a carbon number of 3 to 10, and an aryl group having a carbon number of 6 to 20 or an aralkyl group having a carbon number of 7 to 21. R¹² is a hydrogen atom, linear an alkyl group having a carbon number of 1 to 10, a branched alkyl group having a carbon number of 3 to 10 or cyclic alkyl group having a carbon number of 3 to 10, and an aryl group having a carbon number of 6 to 20 or an aralkyl group having a carbon number of 7 to 21. R¹³, R¹⁴ and R¹⁵ are, independently, a linear alkyl group having a carbon number of 1 to 10, a branched alkyl group having a carbon number of 3 to 10 or cyclic alkyl group having a carbon number of 3 to 10, and an aryl group having a carbon number of 6 to 20 or an aralkyl group having a carbon number of 7 to 21. Two of R¹³, R¹⁴, and R¹⁵ may be bonded to each other to form a ring. * represents a bonding site with an oxygen atom.

Each R³ is independently selected from a group consisting of a hydrogen atom, an alkyl group having a carbon number of 1 or more and 5 or less, a phenyl group, and a fluoroalkyl group having a carbon number of 1 or more and 10 or less. Each R⁴ is independently a hydrogen atom or alkyl group having a carbon number of 1 or more and 5 or less.

d is a number of 1 or more and 3 or less, e is a number of 0 or more and 2 or less, f is a number of 0 or more and less than 3, g is a number more than 0 and 3 or less, and d+e+f+g=4.

When there is a plurality of R¹³, R¹⁴, and R¹⁵, each of them is independently selected from any of the substituents described above.

Specific examples of R³ in the general formula (1) include a hydrogen atom, methyl group, ethyl group, 3,3,3-trifluoropropyl group, and a phenyl group. In addition, specific examples of R⁴ include a hydrogen atom, methyl group, and an ethyl group. In the theoretical values of d, e, f, and g, d is preferably an integer of 1 or 2. e is preferably an integer of 0 or more and 2 or less, more preferably an integer of 0 or 1. f is preferably an integer of 0 or more and 2 or less, more preferably an integer of 0 or 1. g is preferably an integer of 1 to 3, more preferably an integer of 2 or 3. a is preferably 1 or 2.

In addition, d is preferably a number of 1 or more and 2 or less. e is preferably a number of 0 or more and 2 or less, more preferably 0 or more and 1 or less. f is preferably a number of 0 or more and 2 or less, more preferably 0 or more and 1 or less. g is preferably a number of 1 or more and 3 or less, more preferably 2 or more and 3 or less.

Among them, from the viewpoint of manufacturability, the number of HFIP group-containing aryl groups represented by the general formula (1a) in the general formula (1) is preferably 1. That is, the constituent unit in which d is 1 is a particularly preferable example of the constituent unit of the general formula (1).

The group represented by the general formula (1a) in the general formula (1) is particularly preferably any of the groups represented by the general formulas (1aa) to (1ad).

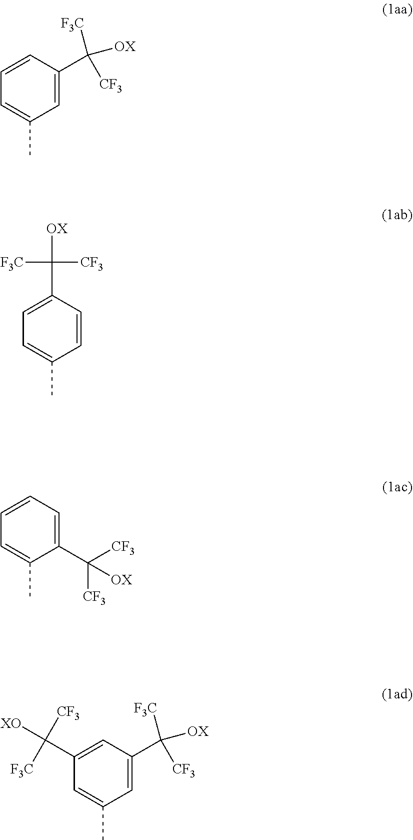

In the general formulas (1aa) to (1ad), the broken lines represent bonds.

In an embodiment, the first constituent unit represented by the general formula (1) preferably consists of a single constituent unit. In this case, “consists of a single constituent unit” means that it is consists of the constituent unit in which the number of a, the number of d, substituent species of R³ and its number e, substituent species of OR⁴ (excluding the hydroxy group and the alkoxy group) and its number f (excluding the number of hydroxy group and alkoxy group among f) in the general formula (1) are the same.

### [Second Constituent Unit Represented by the General Formula (2)]

[(R⁵)ₕ(R⁶)ᵢSiO_{j/2}] (2)

In the general formula (2), R⁵ is a substituent selected from monovalent organic groups having a carbon number of 1 or more and 30 or less substituted by any of an epoxy group, oxetane group, acryloyl group, methacryloyl group, or lactone group. R⁶ is a hydrogen atom, or a substituent selected from the group consisting of a halogen group, an alkyl group having a carbon number of 1 or more and 5 or less, a phenyl group, hydroxy group, an alkoxy group having a carbon number of 1 or more and 3 or less, and a fluoroalkyl group having a carbon number of 1 or more and 10 or less. h is a number of 1 or more and 3 or less, i is a number of 0 or more and less than 3, j is a number more than 0 and 3 or less, and h+l+j=4. When there is a plurality of R⁵ and R⁶, each of them is independently selected from the substituents described above.

In the theoretical values of h, i, and j in the general formula (2), i is preferably an integer of 0 or more and 2 or less, more preferably an integer of 0 or 1. j is preferably an integer of 1 to 3, more preferably an integer of 2 or 3. In addition, from the viewpoint of availability, the value of h is particularly preferably 1. Among these, a constituent unit in which h is 1, i is 0, and j is 3 is particularly preferred example as the constituent unit of the general formula (2). Specific examples of R⁶ include a hydrogen atom, methyl group, ethyl group, phenyl group, methoxy group, ethoxy group, and a propoxy group.

In addition, h is preferably a number of 1 or more and 2 or less, more preferably 1. i is preferably a number of 0 or more and 2 or less, more preferably 0 or more and 1 or less. j is preferably a number of 1 or more and 3 or less, more preferably 2 or more and 3 or less.

In the case where R⁵ group of the second constituent unit represented by the general formula (2) contains an epoxy group, oxetane group, or lactone group, it is possible to impart good adhesion to the patterned cured film obtained from the application liquid for an optical member with various substrates containing silicon, glass, resin, or the like on the contact surface. In addition, in the case where R⁵ group contains an acryloyl group or methacryloyl group, a highly curable film is obtained, and good solvent resistance is obtained. In the case where R⁵ group includes an epoxy group or oxetane group, R⁵ group is preferably a group represented by the following general formulas (2a), (2b), and (2c).

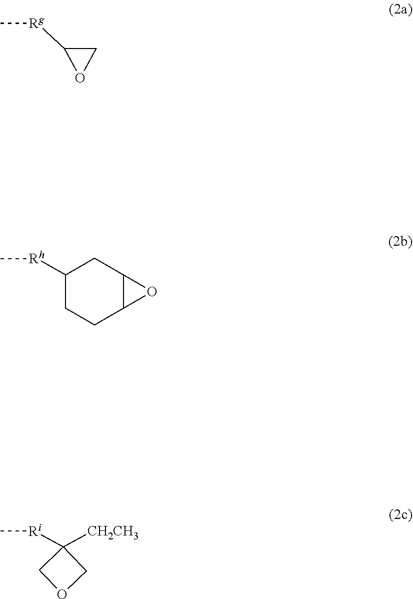

In the general formulas (2a), (2b) and (2c), each R^{g}, R^{h}, Rⁱ is independently a divalent linking group. A broken line represents a bond.

In this case, in the case where R^{g}, R^{h}, and Rⁱ are divalent linking groups, the divalent linking group includes, for example, an alkylene group having a carbon number of 1 to 20, and may include one or more sites forming an ether bond. In the case where the number of carbon atoms is 3 or more, the alkylene group may be branched, or separate carbons may be connected to each other to form a ring. In the case where the number of carbon atoms is 2 or more, oxygen may be inserted between carbon and carbon and may include one or more sites forming an ether bond, and these are preferable examples as the divalent linking group.

Among the second constituent unit represented by the general formula (2), the particularly preferred one is exemplified by the raw material alkoxysilane, and examples thereof include 3-glycidoxypropyltrimethoxysilane (manufactured by Shin-Etsu Chemical Co., Ltd., product name: KBM-403), 3-glycidoxypropyltriethoxysilane (manufactured by Shin-Etsu Chemical Co., Ltd., product name: KBE-403), 3-glycidoxypropylmethyldiethoxysilane (manufactured by Shin-Etsu Chemical Co., Ltd., product name: KBE-402), 3-glycidoxypropylmethyldimethoxysilane (manufactured by Shin-Etsu Chemical Co., Ltd., product name: KBM-402), 2-(3,4-epoxycyclohexyl)ethyltrimethoxysilane (manufactured by Shin-Etsu Chemical Co., Ltd., product name: KBM-303), 2-(3,4-epoxycyclohexyl)ethyltriethoxysilane 8-glycidoxyoctyltrimethoxysilane (manufactured by Shin-Etsu Chemical Co., Ltd., product name: KBM-4803), [(3-ethyl-3-oxetanyl)methoxy]propyltrimethoxysilane, [(3-ethyl-3-oxetanyl)methoxy]propyltriethoxysilane, and the like.

In the case where R⁵ group includes an acryloyl group or methacryloyl group, it is preferably a group selected from the following general formulas (3a) and (4a).

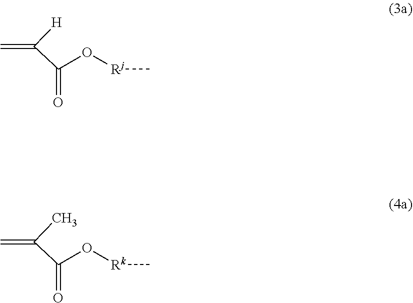

In the general formulas (3a) and (4a), each R^{j} and R^{k} is independently a divalent linking group. A broken line represents a bond.

Preferred examples in the case where R^{j} and R^{k} are divalent linking groups include those listed as preferred groups in R^{g}, R^{h}, and Rⁱ.

Among the second constituent unit represented by the general formula (2), the particularly preferred one is exemplified by the raw material alkoxysilane, and examples thereof include 3-methacryloxypropyltrimethoxysilane (manufactured by Shin-Etsu Chemical Co., Ltd., product name: KBM-503), 3-methacryloxypropyltriethoxysilane (manufactured by Shin-Etsu Chemical Co., Ltd., product name: KBE-503), 3-methacryloxypropylmethyldimethoxysilane (manufactured by Shin-Etsu Chemical Co., Ltd., product name: KBM-502), 3-methacryloxypropylmethyldiethoxysilane (manufactured by Shin-Etsu Chemical Co., Ltd., product name: KBE-502), 3-acryloxypropyltrimethoxysilane (manufactured by Shin-Etsu Chemical Co., Ltd., product name: KBM-5103), 8-methacryloxyoctyltrimethoxysilane (manufactured by Shin-Etsu Chemical Co., Ltd., product name: KBM-5803), and the like.

In the case where R⁵ group includes a lactone group, if it is represented by R⁵—Si structure, it is preferably a group selected from the following general formulas (5-1) to (5-20), general formulas (6-1) to (6-7), general formulas (7-1) to (7-28), or general formulas (8-1) to (8-12).

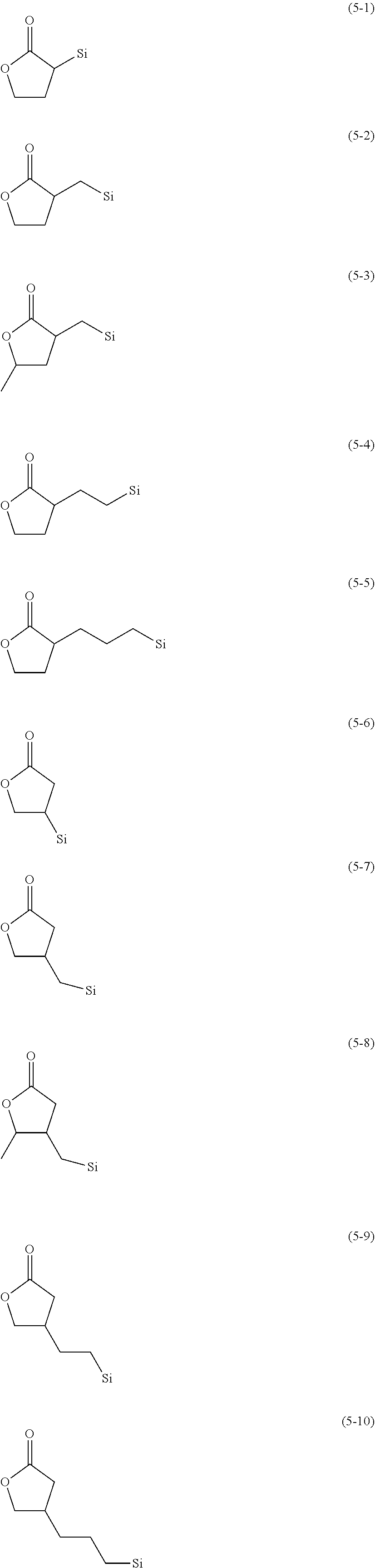

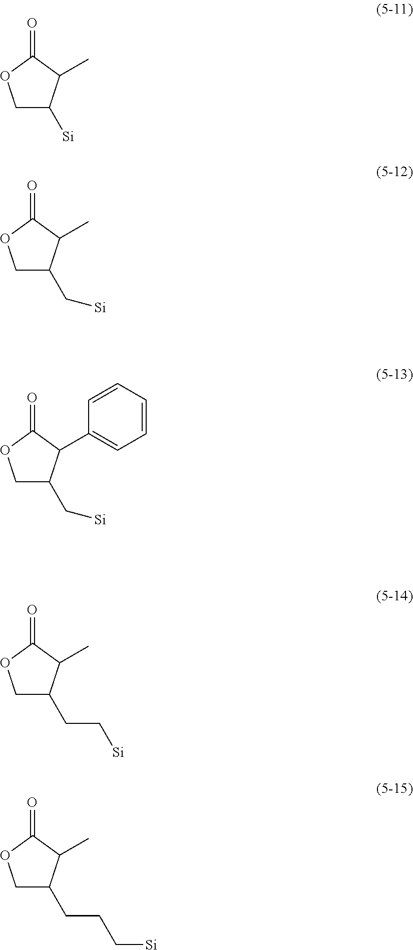

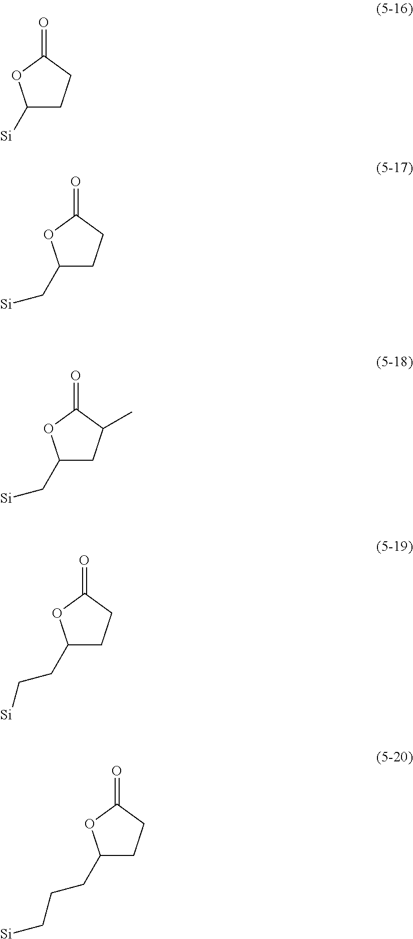

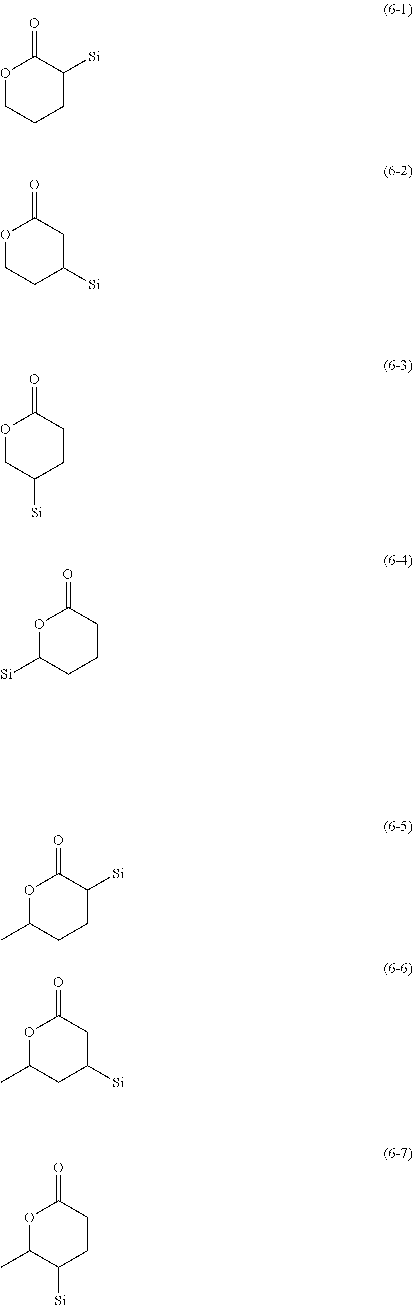

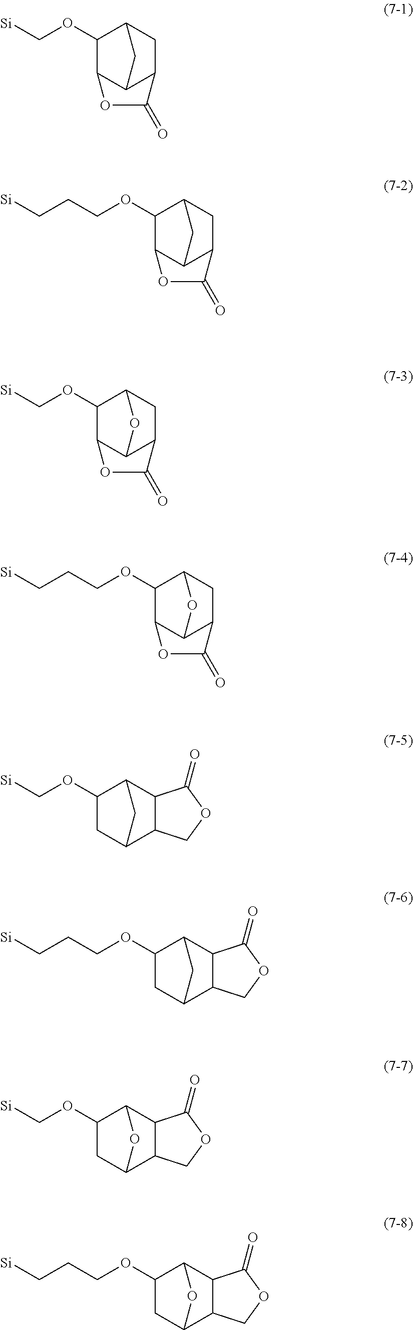

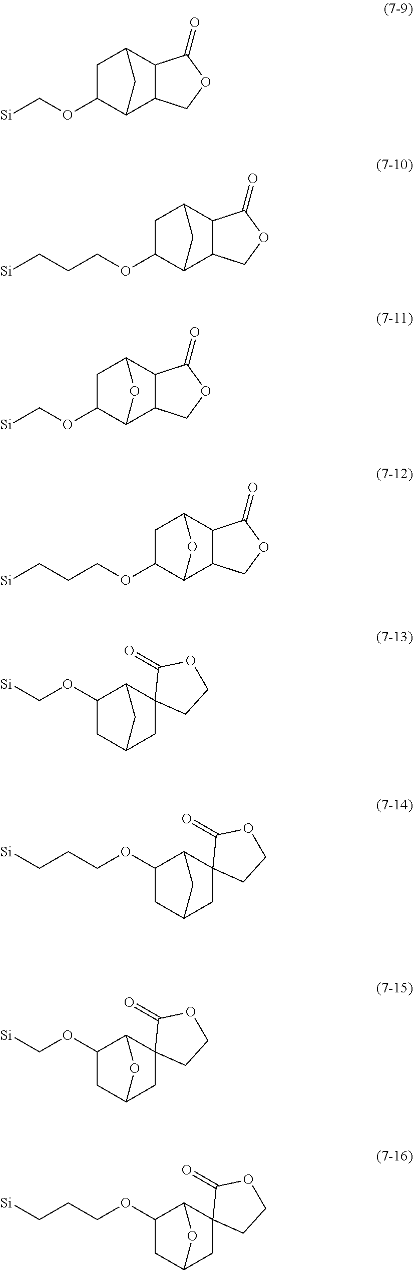

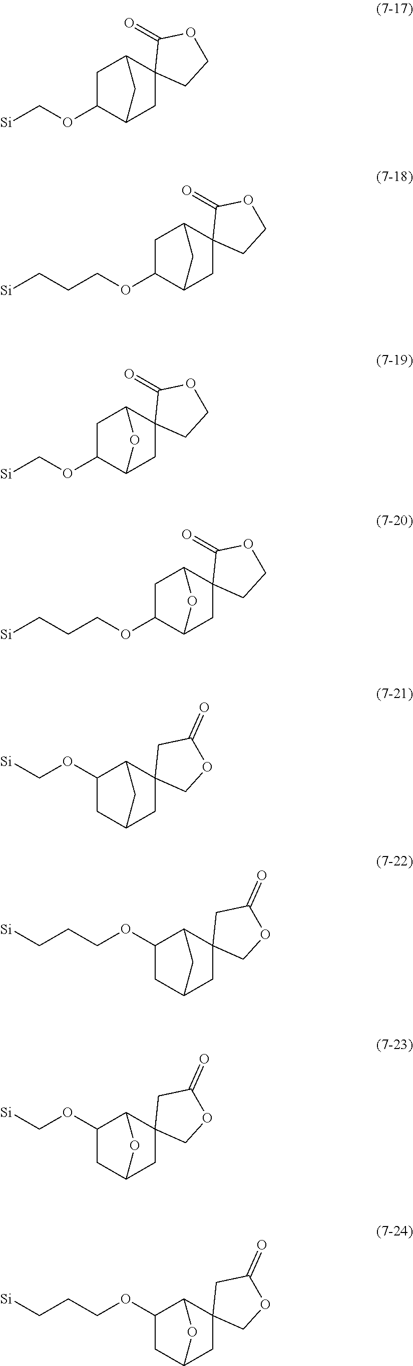

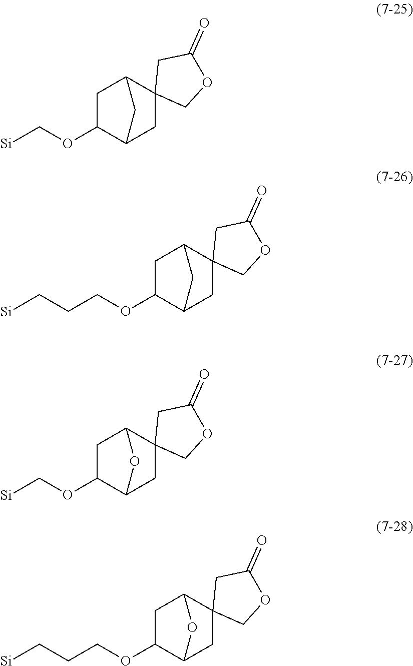

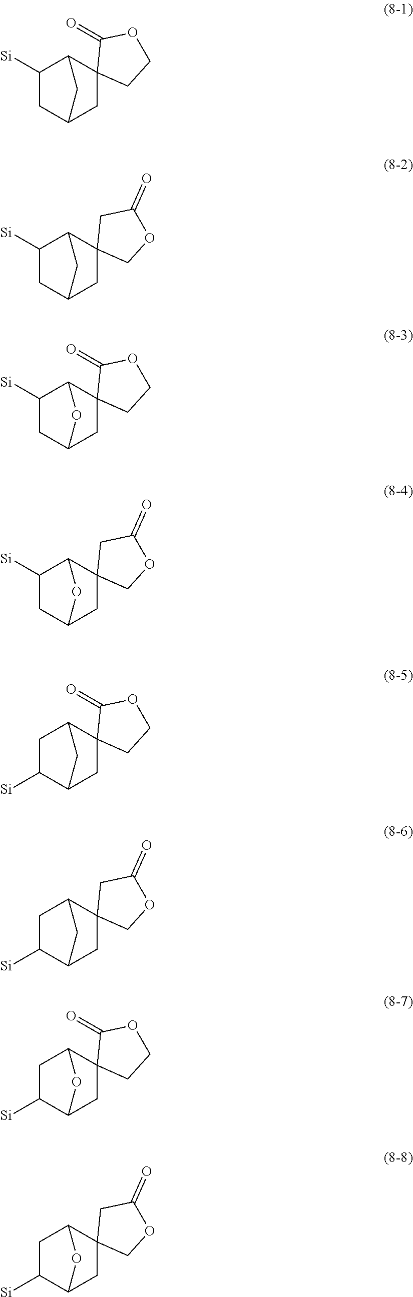

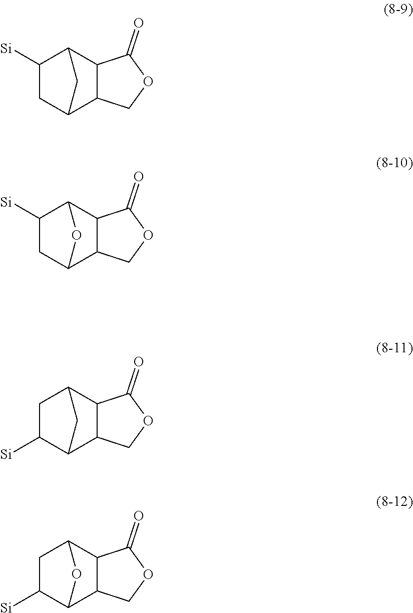

### [A Third Constituent Unit Represented by the General Formula (3)]

[(R⁷)ₖSiO_{l/2}] (3)

In the general formula (3), R⁷ is a substituent selected from a group consisting of a halogen group, alkoxy group, and a hydroxy group.

k is a number of 0 or more and less than 4, l is a number more than 0 and 4 or less, and k+l=4. In addition, k is preferably a number of 0 or more and 3 or less. l is preferably a number of 1 or more and 4 or less.

As described above, O_{l/2} in the general formula (3) may have at least one selected from a group consisting of Q1 to Q4 units. In addition, Q0 unit may be included.

Q0 unit: a structure in which all four bonds of a Si atom are hydrolyzable and polycondensable groups (such as a halogen group, alkoxy group, or hydroxy group that can form siloxane bonds).

Q1 unit: a structure in which one of the four bonds of a Si atom forms a siloxane bond and the other three are all hydrolyzable and polycondensable groups.

Q2 unit: a structure in which two of the four bonds of a Si atom form a siloxane bond and the other two are all hydrolyzable and polycondensable groups.

Q3 unit: a structure in which three of the four bonds of a Si atom form a siloxane bond and the other one is the hydrolyzable and polycondensable group.

Q4 unit: a structure in which all four bonds of a Si atom form a siloxane bond.

Since the third constituent unit represented by the general formula (3) have a configuration close to SiO₂ in which the organic components are eliminated as much as possible, it is possible to impart a chemical solution and heat resistance, transparency, and organic solvent resistance to the cured film or the patterned cured film obtained from the application liquid for an optical member.

The third constituent unit represented by the general-n (3) can be obtained by using tetraalkoxysilane, tetrahalosilane (for example, tetrachlorosilane, tetramethoxysilane, tetraethoxysilane, tetra-n-propoxysilane, tetraisopropoxysilane, or the like) or an oligomer thereof as a raw material, hydrolyzing it, and then polymerizing it (see “polymerization method” described later).

Examples of the oligomer include a silicate compound such as silicate 40 (pentamer on average, manufactured by TAMA CHEMICALS CO., LTD.), ethyl silicate 40 (pentamer on average, manufactured by COLCOAT CO., LTD.), silicate 45 (heptamer on average, manufactured by TAMA CHEMICALS CO., LTD.), M silicate 51 (tetramer on average, manufactured by TAMA CHEMICALS CO., LTD.), methyl silicate 51 (tetramer on average, manufactured by COLCOAT CO., LTD.), methyl silicate 53A (heptamer on average, manufactured by COLCOAT CO., LTD.), ethyl silicate 48 (decamer on average, manufactured by COLCOAT CO., LTD.), EMS-485 (mixed product of ethyl silicate and methyl silicate, manufactured by COLCOAT CO., LTD.). From the viewpoint of ease of handling, a silicate compound is preferably used.

When the total Si atoms of the stabilizer (B) are 100 mol %, the polysiloxane compound (first constituent unit) represented by the general formula (1) is preferably contained in an amount of 5 mol % to 100 mol % of the total constituent units. More preferably, it is contained in an amount of 8 mol % to 100 mol %.

In addition, when the second constituent unit and the third constituent unit are included in addition to the first constituent unit, the ratio of Si atoms of each constituent unit is preferably 0 to 80 mol % in the second constituent unit and 0 to 90 mol % in the third constituent unit (where the total of the second constituent unit and the third constituent unit is 1 to 95 mol %).

In addition, the second constituent unit may be more preferably 2 to 70 mol %, still more preferably 5 to 40 mol %.

In addition, the third constituent unit may be more preferably in the range of less than 5 mol % or more than 50 mol %, even more preferably less than 5 mol % or more than 60 mol %. In the case where the third constituent unit is less than 5 mol %, the lower limit is not limited, but may be, for example, preferably 0 mol % or more, and more preferably more than 0 mol %. In the case where the third constituent unit is more than 50 mol %, the upper limit is not limited, but may be, for example, 95 mol % or less.

For example, the mol % of a Si atom can be determined from the peak area ratio in ²⁹Si NMR.

### [Other Constituent Units (Optional Components)]

In the polysiloxane compound as the stabilizer (B), in addition to the constituent units described above, other constituent units containing Si atoms (hereinafter, sometimes referred to as “optional components”) may be included in order to adjust the solubility in the solvent (C), the heat resistance and the transparency, and the like when the cured film or the patterned cured film is formed. For example, the optional components include chlorosilanes or alkoxysilanes. Chlorosilanes and alkoxysilanes are sometimes referred to as “other Si monomers”.

Specific examples of the chlorosilane include dimethyldichlorosilane, diethyldichlorosilane, dipropyldichlorosilane, diphenyldichlorosilane, bis(3,3,3-trifluoropropyl)dichlorosilane, methyl(3,3,3-trifluoropropyl)dichlorosilane, methyltrichlorosilane, ethyltrichlorosilane, propyltrichlorosilane, isopropyltrichlorosilane, phenyltrichlorosilane, methylphenyltrichlorosilane, trifluoromethyltrichlorosilane, pentafluoroethyltrichlorosilane, and 3,3,3-trifluoropropyltrichlorosilane.

Examples of alkoxysilane include dimethyldimethoxysilane, dimethyldiethoxysilane, dimethyldipropoxysilane, dimethyldiphenoxysilane, diethyldimethoxysilane, diethyldiethoxysilane, diethyldipropoxysilane, diethyldiphenoxysilane, dipropyldimethoxysilane, dipropyldiethoxysilane, diphenyldimethoxysilane, diphenyldiethoxysilane, diphenyldiphenoxysilane, bis(3,3,3-trifluoropropyl)dimethoxysilane, methyl(3,3,3-trifluoropropyl)dimethoxysilane, methyltrimethoxysilane, ethyltrimethoxysilane, propyltrimethoxysilane, isopropyltrimethoxysilane, methylphenyldimethoxysilane phenyltrimethoxysilane, methyltriethoxysilane, methylphenyldiethoxysilane, ethyltriethoxysilane, propyltriethoxysilane, isopropyltriethoxysilane, phenyltriethoxysilane, methyltripropoxysilane, ethyltripropoxysilane, propyltripropoxysilane, isopropyltripropoxysilane, phenyltripropoxysilane, methyltriisopropoxysilane, ethyltriisopropoxysilane, propyltriisopropoxysilane, isopropyltriisopropoxysilane, phenyltriisopropoxysilane, trifluoromethyltrimethoxysilane, pentafluoroethyltrimethoxysilane, 3,3,3-trifluoropropyltrimethoxysilane, and 3,3,3-trifluoropropyltriethoxysilane.

The optional components described above may be used alone or in a mixture of two or more thereof.

Among them, for the purpose of enhancing the heat resistance and transparency of the obtained patterned cured film, phenyltrimethoxysilane, phenyltriethoxysilane, methylphenyldimethoxysilane, and methylphenyldiethoxysilane are preferable, and for the purpose of enhancing the flexibility of the obtained patterned cured film and preventing cracks, dimethyldimethoxysilane and dimethyldiethoxysilane are preferable.

The ratio of Si atoms contained in the optional components when the total Si atoms in the polysiloxane compound as the stabilizer (B) is 100 mol %, is not particularly limited, and may be, for example, 0 to 99 mol %, preferably 0 to 95 mol %, and more preferably 10 to 85 mol %.

The molecular weight of the polysiloxane compound as the stabilizer (B) may be 500 to 50,000 in terms of weight average molecular weight (Mw), and is preferably 800 to 40,000, and more preferably 1,000 to 30,000. In addition, more preferably, the polysiloxane compound is an oligomer, and the molecular weight may be 500 or more and less than 3,000 in weight average molecular weight (Mw). The molecular weight can be within a desired range by adjusting the amount of the catalyst and the temperature of the polymerization reaction. In addition, the dispersity (Mw/Mn) which can be calculated from the weight average molecular weight (Mw) and the number-average molecular weight (Mn) can be, for example, 1.01 to 6.0, and preferably 1.01 to 5.0. In the case where the component (A) described above is the metal fine particles (A-1), the dispersity (Mw/Mn) may be more preferably 1.01 to 3.0.

### [Polymerization Method of Polysiloxane Compound]

Next, a polymerization method for obtaining the polysiloxane compound as the stabilizer (B) will be described. The polysiloxane compound which is the desired stabilizer (B) is obtained by a hydrolysis polycondensation reaction using halosilanes represented by the general formula (9) for obtaining the first constituent unit, alkoxysilane represented by the general formula (10), a raw material for obtaining the second constituent unit described above, a raw material for obtaining the third constituent unit described above, and other Si monomers. Therefore, the polysiloxane compound which is the stabilizer (B) is also a hydrolysis polycondensate.

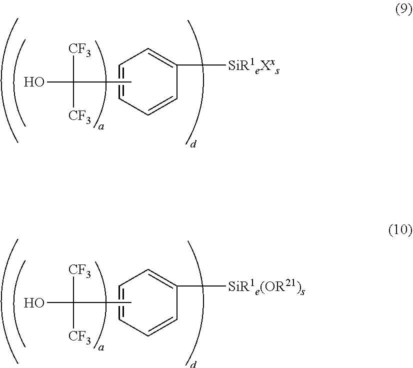

In the general formulas (9) and (10), X^{x} is a halogen atom, R²¹ is an alkyl group, a is an integer of 1 to 5, d is an integer of 1 to 3, e is an integer of 0 to 2, and s is an integer of 1 to 3, and d+e+s=4.

The hydrolysis polycondensation reaction can be carried out by a general method for the hydrolysis and condensation reaction of halosilanes (preferably chlorosilanes) and alkoxysilane.

As a specific example, first, halosilanes and alkoxysilane are collected in a predetermined amount in a reaction vessel at room temperature (in particular, an ambient temperature not heated or cooled, and usually about 15° C. or more and about 30° C. or less; the same shall apply hereinafter), and then water for hydrolyzing halosilanes and alkoxysilane, a catalyst for causing the polycondensation reaction to proceed, and, if desired, a reaction solvent are added to the reaction vessel to form a reaction solution. In this case, the order in which the reaction materials are charged is not limited to this, and the reaction solution can be prepared by charging the reaction materials in any order. In the case where other Si monomers are used in combination, they may be added to the reaction vessel as well as halosilanes and alkoxysilane.

Then, the reaction solution is stirred, and the hydrolysis condensation is allowed to proceed at a predetermined temperature for a predetermined period of time to obtain the polysiloxane compound as the stabilizer (B). The time required for the hydrolysis condensation depends on the type of the catalyst, and is usually 3 hours or more and 24 hours or less, and the reaction temperature is room temperature (for example, 25° C.) or more and 200° C. or less. In the case where heating is performed, in order to prevent the unreacted raw material, water, the reaction solvent, and/or the catalyst in the reaction system from being distilled off to the outside of the reaction system, it is preferable that the reaction vessel is a closed system or a reflux device such as a condenser is attached to reflux the reaction system. After the reaction, from the viewpoint of handling the polysiloxane compound which is the stabilizer (B), it is preferable to remove the water remaining in the reaction system, the alcohol to be formed, and the catalyst. The removal of water, alcohol, and catalyst may be carried out in an extraction operation, or a solvent such as toluene that does not adversely affect the reaction may be added to the reaction system and azeotropically removed in a Dean-Stark tube.

The amount of water used in the hydrolysis and condensation reaction is not particularly limited. From the viewpoint of reaction efficiency, the amount is preferably 0.01 times or more and 15 times or less with respect to the total number of moles of the hydrolyzable groups (alkoxy group and halogen atom group) contained in the alkoxysilane and halosilanes as the raw material.

The catalyst for carrying out the polycondensation reaction is not particularly limited, but an acid catalyst or a base catalyst is preferably used. Specific examples of the acid catalyst include hydrochloric acid, nitric acid, sulfuric acid, hydrofluoric acid, phosphoric acid, acetic acid, oxalic acid, trifluoroacetic acid, methanesulfonic acid, trifluoromethanesulfonic acid, camphorsulfonic acid, benzenesulfonic acid, tosylic acid, a polyhydric carboxylic acid such as formic acid, maleic acid, malonic acid, or succinic acid, or anhydrides thereof. Specific examples of the base catalyst include triethylamine, tripropylamine, tributylamine, tripentylamine, trihexylamine, triheptylamine, trioctylamine, diethylamine, triethanolamine, diethanolamine, sodium hydroxide, potassium hydroxide, sodium carbonate, and tetramethylammonium hydroxide. The amount of the catalyst to be used is preferably 0.001 times or more and 0.5 times or less with respect to the total number of moles of the hydrolyzable groups (alkoxy group and halogen atom group) contained in the alkoxysilane and halosilanes as the raw material.

In the hydrolysis and condensation reaction, the reaction solvent is not necessarily used, and the raw material compound, water, and the catalyst can be mixed and hydrolyzed and condensed. On the other hand, when a reaction solvent is used, the type thereof is not particularly limited. Among them, from the viewpoint of solubility in a raw material compound, water, and a catalyst, a polar solvent is preferable, and an alcohol-based solvent is more preferable. Specific examples thereof include methanol, ethanol, 1-propanol, 2-propanol, 1-butanol, 2-butanol, diacetone alcohol, and propylene glycol monomethyl ether. The amount of the reaction solvent can be any amount necessary for the hydrolysis condensation reaction to proceed in a homogeneous system. The solvent (C) described later may be used as the reaction solvent.

### [Method for Synthesizing Raw Material Compound of Constituent Unit of General Formula (1)]

The alkoxysilanes represented by the general formula (10) and the halosilanes represented by the general formula (9), which are polymerization raw materials for providing the first constituent unit of the general formula (1), are known compounds described in International Patent Publication No. 2019/167770, and may be synthesized according to the description of publicly known literature.

### [Solvent (C)]

The solvent (C) may include at least one compound selected from a group consisting of propylene glycol monomethyl ether acetate, propylene glycol monomethyl ether, cyclohexanone, ethyl lactate, γ-butyrolactone, diacetone alcohol, diglyme, methyl isobutyl ketone, 3-methoxybutyl acetate, 2-heptanone, N,N-dimethylformamide, N,N-dimethylacetamide, N-methylpyrrolidone, glycols, glycol ethers, and glycol ether esters.

Specific examples of the glycol, glycol ether, and glycol ether ester include CELTOL (registered trademark) manufactured by Daicel Corporation and HISOLV (registered trademark) manufactured by TOHO CHEMICAL INDUSTRY COMPANY, LIMITED. Examples thereof include, but not limited to, cyclohexanol acetate, dipropylene glycol dimethyl ether, propylene glycol diacetate, dipropylene glycol methyl-n-propyl ether, dipropylene glycol methyl ether acetate, 1,4-butanediol diacetate, 1,3-butylene glycol diacetate, 1,6-hexanediol diacetate, 3-methoxybutylacetate, ethylene glycol monobutyl ether acetate, diethylene glycol monoethyl ether acetate, diethylene glycol monobutyl ether acetate, triacetin, 1,3-butylene glycol, propylene glycol-n-propyl ether, propylene glycol-n-butyl ether, dipropylene glycol methyl ether, dipropylene glycol ethyl ether, dipropylene glycol-n-propyl ether, dipropylene glycol-n-butyl ether, tripropylene glycol methyl ether, tripropylene glycol-n-butyl ether, triethylene glycol dimethyl ether, diethylene glycol butyl methyl ether, tripropylene glycol dimethyl ether, and triethylene glycol dimethyl ether.

In an embodiment, the amount of the solvent (C) contained in the application liquid for an optical member is preferably 20% by mass or more and 95% by mass or less, and more preferably 30% by mass or more and 90% by mass or less. Setting the content of the solvent within the range described above makes it easier to coat and form a resin film uniformized with an appropriate thickness. In addition, the solvent (C) may be used by combining two or more of the solvents described above.

### [Additive (Optional Components)]

In an embodiment, the application liquid for an optical member may contain the following components as an additive as long as the excellent properties of the application liquid are not significantly impaired.

For example, an additive such as a surfactant may be contained in order to improve coatability, leveling property, film formability, storage stability, defoaming property, and the like. Specific examples thereof include commercially available surfactants, product name: MEGAFAC, product number: F142D, F172, F173, or F183, manufactured by DIC Corporation, product name: Fluorad, product number: FC-135, FC-170C, FC-430, or FC-431, manufactured by 3M Japan Limited., product name: SURFLON, product number: S-112, S-113, S-131, S-141, or S-145, manufactured by AGC Seimi Chemical Co., Ltd., or product name: SH-28PA, SH-190, SH-193, SZ-6032, or SF-8428, manufactured by Toray Dow Corning Silicone Co., Ltd.

In the case where these surfactants are added, the blending amount thereof is preferably 0.001 parts by mass or more and 10 parts by mass or less with respect to 100 parts by mass of the constituent unit represented by the general formula (1) in the polysiloxane compound as the stabilizer (B) or the polymer described later. In addition, MEGAFAC is a product name of a fluorine-based additive (surfactant/surface modifier) manufactured by DIC Corporation, Fluorad is a product name of a fluorine-based surfactant manufactured by 3M Japan Limited., and SURFLON is a product name of a fluorine-based surfactant manufactured by AGC Seimi Chemical Co., Ltd., and each of them is registered as a trademark.

In order to improve chemical solution resistance of the obtained cured film or patterned cured film, a curing agent can be blended as another component. Examples of the curing agent include a melamine curing agent, a urea resin curing agent, a polybasic acid curing agent, an isocyanate curing agent, and an epoxy curing agent. It is considered that the curing agent mainly reacts with a hydroxy group or alkoxy group contained in each constituent unit of the polysiloxane compound as component (B), the metal fine particles as component (A), and the metal compound to form a crosslinked structure.

Specific examples thereof include isocyanates such as isophorone diisocyanate, hexamethylene diisocyanate, tolylene diisocyanate, or diphenylmethane diisocyanate, and isocyanurates thereof, blocked isocyanates thereof, or a biurets thereof. amino compounds such as melamine resins such as alkylated melamine, methylol melamine, imino melamine, and urea resins or epoxy curing agents having two or more epoxy groups obtained by reacting polyhydric phenol such as bisphenol A with epichlorohydrin. Specifically, a curing agent having a structure represented by a general formula (11) is more preferable, and specifically, a melamine derivative or a urea derivative represented by the general formulas (11a) to (11d) (product name: NIKALAC, manufactured by SANWA CHEMICAL CO., LTD.) is exemplified (in the general formula (11), a broken line means a bond).

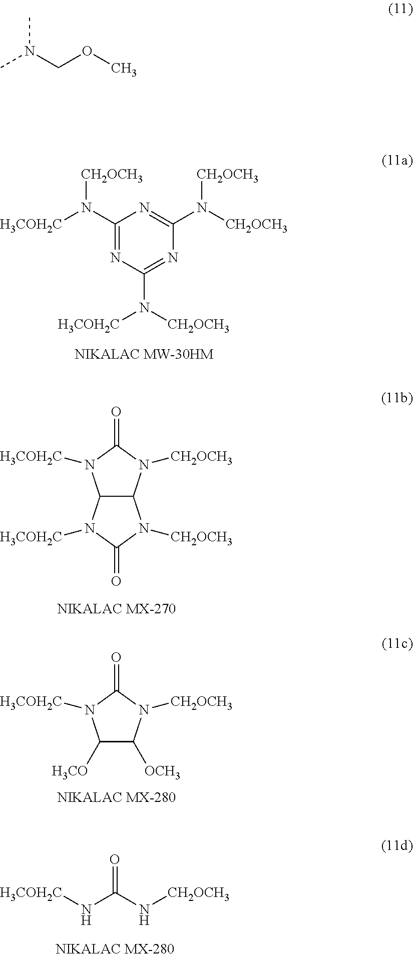

In the case where these curing agents are added, the blending amount thereof is preferably 0.001 parts by mass or more and 10 parts by mass or less with respect to 100 parts by mass of the constituent unit represented by the general formula (1) in the polysiloxane compound as the stabilizer (B) or the polymer described later.

### [Polymer]

The polymer includes the constituent unit represented by the general formula (1) and the constituent unit represented by the general formula (1-A). Preferably, the polymer may be an oligomer-level copolymer including the constituent unit represented by the general formula (1) and the constituent unit represented by the general formula (1-A).

The weight average molecular weight and the dispersity of the polymer may be the same as those of the polysiloxane compound described above. Particularly in the case of a copolymer, the molecular weight may be at the oligomer level, for example, the weight average molecular weight (Mw) may be from 500 to 50,000, preferably from 500 to 40,000, more preferably from 500 to 30,000, still more preferably from 800 to 10,000, particularly preferably from 900 to 3,000, and most preferably from 1,000 to less than 3,000. In addition, if it is the oligomer-level copolymer, the dispersity (Mw/Mn) can be, for example, 1.01 to 6.0, preferably 1.1 to 5.0.

### [Method for Producing Polymer]

A polymer including the constituent unit represented by the general formula (1) and the constituent unit represented by the general formula (1-A) described above can be produced by hydrolysis polycondensation of a silicon compound represented by the following general formula (1y) and a metal compound represented by the following general formula (1-2). The hydrolysis polycondensation can be performed by the same method as the polymerization method for obtaining the polysiloxane compound as the stabilizer (B) described above.

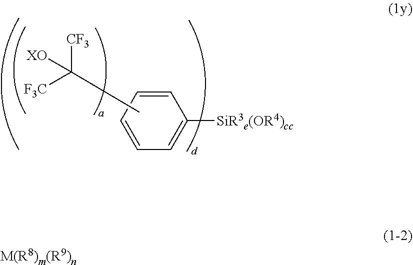

In the general formula (1y), R³ is independently a hydrogen atom, an alkyl group having a carbon number of 1 or more and 5 or less, a phenyl group, and a fluoroalkyl group having a carbon number of 1 or more and 10 or less.

Each R⁴ is independently a hydrogen atom or an alkyl group having a carbon number of 1 or more and 5 or less.

a is a number of 1 to 5, d is a number of 1 or more and 3 or less, e is a number of 0 or more and 2 or less, cc is a number of 1 or more and 3 or less, and d+e+cc=4.

X is a hydrogen atom or an acid-labile group.

Preferred examples of the silicon compound represented by the general formula (1y) include a group represented by the general formula (1a), which is a partial structure, is,

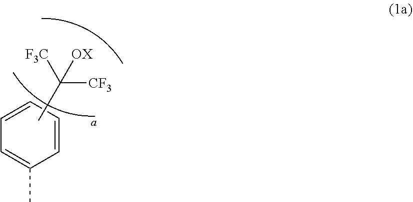

any of the groups represented by the general formulas (1aa) to (1ad).

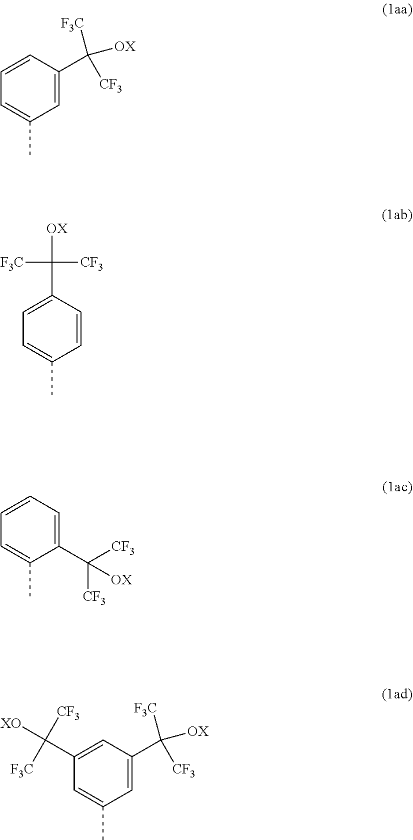

In the general formula (1-2), M is at least one selected from the group consisting of Ti, Zr, Al, Hf, In, and Sn.

Each R⁸ is independently selected from the group consisting of a hydrogen atom, hydroxyl group, halogen group, an alkoxy group having a carbon number of 1 or more and 5 or less, an alkyl group having a carbon number of 1 or more and 5 or less, a phenyl group, and a fluoroalkyl group having a carbon number of 1 or more and 10 or less.

R⁹ is alkoxy having a carbon number of 1 to 5 or a halogen.

M is a number of 0 or more and 3 or less, n is a number of 1 or more and 4 or less, and m+n=3 or 4.

Preferred examples of the metal compound represented by the general formula (1-2) are Ti and Zr for M, a halogen group, and an alkoxy group having a carbon number of 1 or more and 5 or less for R⁸. Specific examples thereof include tetrachlorotitanium, tetramethoxytitanium, tetraethoxytitanium, tetra(i-propoxy)titanium, tetra(n-butoxy)titanium, tetraamyloxytitanium, tetraaryloxytitanium, tetraphenoxytitanium, titanium dipropoxybisethylacetoacetate, titanium dibutoxybisethylacetoacetate, titanium dipropoxybis 2,4-pentanedionate, titanium dibutoxybis 2,4-pentanedionate, tetrachlorozirconium, tetramethoxyzirconium, tetraethoxyzirconium, tetra(i-propoxy)zirconium, tetra(n-butoxy)zirconium, tetraphenoxyzirconium, zirconium dibutoxide bis(2,4-pentanedionate), zirconium dipropoxide bis(2,2,6,6-tetramethyl-3,5-heptanedionate).

The ratio of each of the silicon compound represented by the general formula (1y) and the metal compound represented by the general formula (1-2) at the time of hydrolysis polycondensation is preferably 1% by mass to 90% by mass of the constituent unit represented by (1-A) when the sum of the aforementioned silicon compound and the aforementioned metal compound is 100% by mass.

In an embodiment, the addition of a chelator to the metal compound represented by the general formula (1-2) at the time of the hydrolysis polycondensation and/or before the time is preferred because the reaction uniformity of the hydrolysis polycondensation is improved. Examples of the chelator can include β-diketones such as acetylacetone, benzoylacetone, and dibenzoylmethane, and β-keto acid esters such as ethyl acetoacetate and ethyl benzoylacetate.

### [Method for Producing Application Liquid for Optical Member]

The application liquid for an optical member can be produced by mixing the component (A), the stabilizer (B), and the solvent (C) described above by known methods. During mixing, it is preferable to disperse the metal fine particles (A-1) so as not to cause sedimentation. In the application liquid for the member, it is presumed that the HFIP group enhances compatibility with the component (A) described above by including the polysiloxane compound including the first constituent unit represented by the general formula (1), and as a result, it is considered that the application liquid and the photosensitive application liquid can be realized in which the content of the component (A) is increased and the sedimentation derived from the raw material such as the component (A) is suppressed. In addition, the metal fine particles (A-1) may preferably be metal oxide fine particles. The above-described additive may be contained in the application liquid for an optical member as an optional component.

In addition, the application liquid for an optical member can be produced by mixing the above-described polymer and the solvent (C) by known methods. Alternatively, an application liquid for an optical member containing the above-described polymer and the solvent (C) may be obtained by synthesizing the above-described polymer in the solvent (C). The type and suitable content of the solvent (C) are as described above. In the application liquid for an optical member, the silicon compound represented by the general formula (1y) and the metal compound represented by the general formula (1-2) are subjected to hydrolysis polycondensation in advance to obtain a polymer, so that the constituent unit represented by the general formula (1-A) and the constituent unit represented by the general formula (1) are uniformly present in the polymer. As a result, it is considered that sedimentation can be suppressed.

In addition, the additives described above may be added as optional components when the polymer is synthesized and/or when the polymer is mixed with the solvent (C). In addition, the application liquid containing the polymer and the solvent (C) may further contain metal fine particles. The metal fine particles may be the same as those used in mixing the component (A), the stabilizer (B), and the solvent (C) to obtain the application liquid for an optical member.

### [Cured Film]

A preferred embodiment of the present disclosure is a cured film obtained by curing the application liquid for an optical member. The cured film can be formed by applying the application liquid for an optical member onto a substrate and drying the application liquid. In an embodiment, after the application liquid is applied onto the substrate, the application liquid is solidified by heating at a temperature of 80° C. or higher and 350° C. or lower to form the cured film.

### [Photosensitive Application Liquid]

In an embodiment, the application liquid for an optical member may be used as a photosensitive application liquid. In this case, the photosensitive application liquid further includes a photoinduced compound (D) in addition to the application liquid for an optical member.

### [Photoinduced Compound (D)]

Examples of the photoinduced compound (D) include, but are not limited to, at least one selected from a group consisting of naphthoquinonediazide, a photoacid generator, a photobase generator, and a photoradical generator.

When exposed to light, a quinonediazide compound releases nitrogen molecules and decomposes to generate carboxylic acid group in the molecule, thereby improving the solubility of a photosensitive application film obtained from the photosensitive application liquid described above in an alkaline developer. In addition, the alkali solubility of the photosensitive application film in the unexposed portion is suppressed. Therefore, the photosensitive application film containing the quinonediazide compound has a contrast of solubility in the alkali developer at unexposed and exposed portions, so that a positive pattern can be formed.

For example, the quinonediazide compound is a compound having quinonediazide group, such as 1,2-quinonediazide group. Examples of the 1,2-quinonediazide compound include 1,2-naphthoquinone-2-diazide-4-sulfonic acid, 1,2-naphthoquinone-2-diazide-5-sulfonic acid, 1,2-naphthoquinone-2-diazide-4-sulfonyl chloride, and 1,2-naphthoquinone-2-diazide-5-sulfonyl chloride. Using the quinonediazide compound makes it possible to obtain a positive photosensitive application film that is sensitive to an i-line (wavelength 365 nm), an h-line (wavelength 405 nm), and a g-line (436 nm) of a mercury lamp, which are common ultraviolet rays.

Examples of commercially available quinonediazide compounds include NT series, 4NT series, and PC-5, manufactured by Toyo Gosei Co., Ltd., TKF series, and PQ-C manufactured by SANBO CHEMICAL IND. CO., LTD.

The blending amount of the quinonediazide compound as the photoinduced compound (D) in the photosensitive application liquid is not necessarily limited, but is preferably 1 part by mass or more and 30 parts by mass or less, and more preferably 5 parts by mass or more and 20 parts by mass or less, for example, when the constituent unit represented by the general formula (1) in the polysiloxane compound as the stabilizer (B) or the polymer is 100 parts by mass. Using an appropriate amount of the quinonediazide compound makes it easy to achieve both sufficient patterning performance and optical properties such as transparency and refractive index of the obtained patterned cured film.

The photoacid generator will be described. The photoacid generator is a compound that generates an acid upon irradiation with light, and the acid generated at the exposed portion promotes the silanol condensation reaction, that is, the sol-gel polymerization reaction, and the dissolution rate by the alkali developer is remarkably lowered, that is, resistance to the alkali developer can be realized. In addition, in the case where the constituent unit represented by the general formula (1) in the polysiloxane compound as the stabilizer (B) or the polymer has an epoxy group or oxetane group, it is preferable to accelerate each curing reaction. On the other hand, the unexposed portion is dissolved by the alkaline developer without causing this action, and a negative pattern corresponding to the shape of the exposed portion is formed.

Specific examples of the photoacid generator include sulfonium salts, iodonium salts, sulfonyldiazomethanes, N-sulfonyloxyimides, and oxime-O-sulfonates. These photoacid generators may be used alone or in a mixture of two or more thereof. Specific examples of the commercially available product include, but are not limited to, product name: Irgacure 290, Irgacure PAG121, Irgacure PAG103, Irgacure CG11380, Irgacure CG1725 (manufactured by BASF, USA), product name: PAI-101, PAI-106, NAI-105, NAI-106, TAZ-110, TAZ-204 (manufactured by Midori Kagaku Co., Ltd.), product name: CPI-200K, CPI-210S, CPI-101A, CPI-110A, CPI-100P, CPI-110P, CPI-310B, CPI-100TF, CPI-110TF, HS-1, HS-1A, HS-1P, HS-1N, HS-1TF, HS-1NF, HS-1MS, HS-1CS, LW-S1, LW-S1NF (manufactured by San-Apro Ltd.), product name: TFE-triazine, TME-triazine, or MP-triazine (manufactured by SANWA CHEMICAL CO., LTD.).

The blending amount of the photoacid generator as the photoinduced compound (D) in the photosensitive application liquid is not necessarily limited, but is preferably, for example, 0.01 parts by mass or more and 10 parts by mass or less, and more preferably 0.05 parts by mass or more and 5 parts by mass or less, when the constituent unit represented by the general formula (1) in the polysiloxane compound as the stabilizer (B) or the polymer is 100 parts by mass. Using an appropriate amount of the photoacid generator makes it easy to achieve both sufficient patterning performance and storage stability of the composition.

Next, the photobase generator will be described. The photobase generator is a compound that generates a base (anion) upon irradiation with light, and the base generated at the exposed portion causes the sol-gel reaction to proceed, so that the dissolution rate by the alkali developer is remarkably lowered, that is, resistance to the alkali developer can be realized. On the other hand, the unexposed portion is dissolved by the alkaline developer without causing this action, and a negative pattern corresponding to the shape of the exposed portion is formed.

Specific examples of the photobase generator include amides, amine salts, and the like. Specific examples of the commercially available product include, but are not limited to, WPBG-165, WPBG-018, WPBG-140, WPBG-027, WPBG-266, WPBG-300, WPBG-345 (manufactured by FUJIFILM Wako Pure Chemical Corporation), 2-(9-Oxoxanthen-2-yl)propionic Acid 1,5,7-Triazabicyclo[4.4.0]dec-5-ene Salt, 2-(9-Oxoxanthen-2-yl)propionic Acid, Acetophenone O-Benzoyloxime, 2-Nitrobenzyl Cyclohexylcarbamate, 1,2-Bis(4-methoxyphenyl)-2-oxoethyl Cyclohexylcarbamate (manufactured by Tokyo Chemical Industry Co., Ltd.), and EIPBG, EITMG, EINAP, NMBC (manufactured by EIWEISS Chemical Corporation).

These photoacid generators and photobase generators may be used alone or in combination with two or more kinds or in combination with other compounds.

Specific examples of the combination with other compounds include combinations with amines such as 4,4′-bis(dimethylamino)benzophenone, 4,4′-bis(diethylamino)benzophenone, diethanolmethylamine, dimethylethanolamine, triethanolamine, ethyl-4-dimethylaminobenzoate, and 2-ethylhexyl-4-dimethylaminobenzoate, and combinations of these with iodonium salts such as diphenyliodonium chloride, combinations with dyes such as methylene blue, and amines.

The blending amount of the photobase generator as the photoinduced compound (D) in the photosensitive application liquid is not necessarily limited, but is preferably, for example, 0.01 parts by mass or more and 10 parts by mass or less, and more preferably 0.05 parts by mass or more and 5 parts by mass or less, when the constituent unit represented by the general formula (1) in the polysiloxane compound as the stabilizer (B) or the polymer is 100 parts by mass. Using the photobase generator in the amounts indicated here makes it possible to balance the chemical solution resistance of the resulting patterned cured film and the storage stability of the composition.

In addition, the photosensitive application liquid may further contain a sensitizer. Containing the sensitizer promotes the reaction of the photoinduced compound (D) in the exposure processing, and the sensitivity and the pattern resolution are improved.

The sensitizer is not particularly limited, but preferably a sensitizer which is vaporized by heat treatment or a sensitizer which is bleached by light irradiation is used. The sensitizer needs to have light absorption with respect to exposure wavelengths (for example, 365 nm (i-line), 405 nm (h-line), or 436 nm (g-line)) in the exposure processing, but if the sensitizer remains in the patterned cured film as it is, absorption is present in the visible-light area, and thus the transparency is lowered. Therefore, in order to prevent a decrease in transparency caused by the sensitizer, the sensitizer used is preferably a compound which is vaporized by a heat treatment such as thermal curing, or a compound which is bleached by light irradiation such as bleaching exposure described later.

Specific examples of the sensitizer vaporized by the above heat treatment and the sensitizer bleached by light irradiation include coumarin such as 3,3′-carbonylbis(diethylaminocoumarin), anthraquinone such as 9,10-anthraquinone, aromatic ketones such as benzophenone, 4,4′-dimethoxybenzophenone, acetophenone, 4-methoxyacetophenone, benzaldehyde, and condensed aromatics such as biphenyl, 1,4-dimethylnaphthalene, 9-fluorenone, fluorene, phenanthrene, triphenylene, pyrene, anthracene, 9-phenylanthracene, 9-methoxyanthracene, 9,10-diphenylanthracene, 9,10-bis(4-methoxyphenyl)anthracene, 9,10-bis(triphenylsilyl)anthracene, 9,10-dimethoxyanthracene, 9,10-diethoxyanthracene, 9,10-dipropoxyanthracene, 9,10-dibutoxyanthracene, 9,10-dipentaoxyanthracene, 2-t-butyl-9,10-dibutoxyanthracene, and 9,10-bis(trimethylsilylethynyl)anthracene. Examples of commercially available materials include ANTHRACURE (manufactured by Kawasaki Kasei Chemicals Ltd.).

In the case where these sensitizers are added, the blending amount thereof is preferably 0.001 parts by mass or more and 10 parts by mass or less with respect to 100 parts by mass of the constituent unit represented by the general formula (1) in the polysiloxane compound as the stabilizer (B) or the polymer.

In addition, whether the sensitizers described above are used alone or in a mixture of two or more thereof may be appropriately determined by a person skilled in the art depending on the application, usage environment, and restriction.

### [Patterning Method Using Photosensitive Application Liquid]

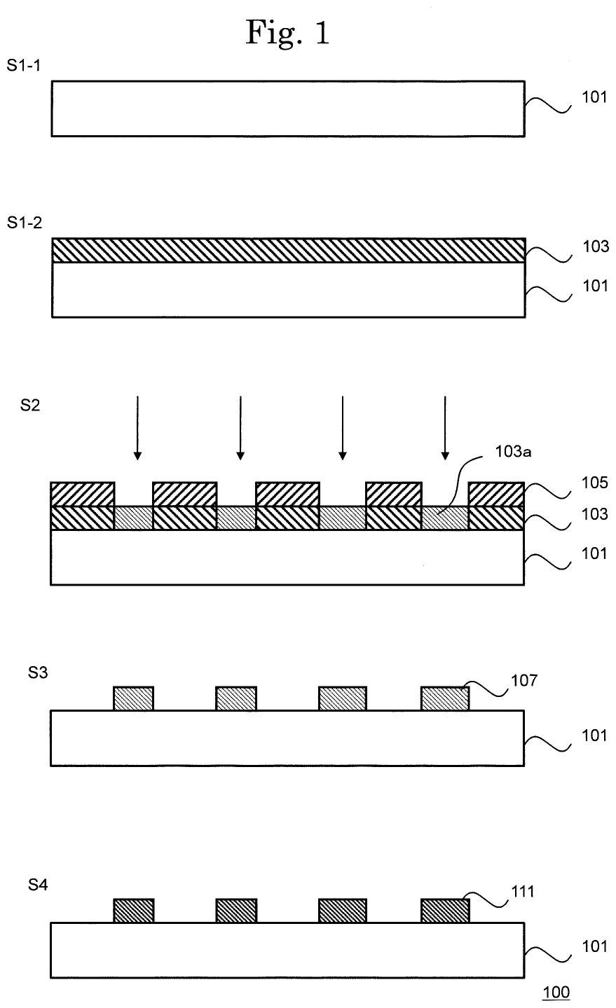

Next, a patterning method using the photosensitive application liquid (also referred to as a “method for producing a patterned cured film” in the present specification) will be described. FIG. 1 is a schematic diagram illustrating a method of manufacturing a negative patterned cured film 100 according to an embodiment of the present invention. The photosensitive application liquid can also produce a positive patterned cured film 100.

One preferred embodiment of the present disclosure is a patterned cured film having a site formed by curing the photosensitive application liquid. The “patterned cured film” in the present specification is preferably a cured film in which a pattern is formed by development after exposure and the obtained pattern is cured as described below.

The method for producing the patterned cured film 100 may include the following first to fourth steps.

First step: a step of applying the photosensitive application liquid onto a substrate 101 and heating the application liquid to form a photosensitive application film 103.

Second step: exposing the photosensitive application film 103 via a photomask 105.

Third step: developing the exposed photosensitive application film 103 to form a patterned film 107.

Fourth step: heating the patterned film 107, thereby curing the patterned film 107 and converting it into a patterned cured film 111.

### [First Step]

The substrate 101 is prepared (step S1-1). The substrate 101 to which the photosensitive application liquid is applied is selected from a silicon wafer, a metal, a glass, a ceramic, and a plastic substrate depending on the application of the patterned cured film to be formed. Specific examples of the substrate used in a semiconductor or a display include silicon, silicon nitride, glass, polyimide (Kapton), polyethylene terephthalate, polycarbonate, and polyethylene naphthalate. In addition, the substrate 101 may have any layer such as silicon, metal, glass, ceramic, or resin on the surface thereof, and “on the substrate” may be a surface of the substrate or via the layer.

A known coating method such as spin coating, dip coating, spray coating, bar coating, applicator, ink jet or roll coater can be used as a coating method on the substrate 101 without any particular limitation.

Thereafter, the substrate 101 coated with the photosensitive application liquid is heated, whereby the photosensitive application film 103 can be obtained (step S1-2). In the heat treatment, the solvent may be removed to such an extent that the obtained photosensitive application film 103 does not easily flow or deform, and it may be heated under conditions of, for example, 80° C. to 120° C. for 30 seconds or more and 5 minutes or less.

### [Second Step]

Next, the photosensitive application film 103 obtained in the first step is shielded by the light-shielding plate (photomask) 105 having a desired shape for forming a desired pattern, and the photosensitive application film 103 is irradiated with light and subjected to the exposure processing to obtain the exposed photosensitive application film 103 (step S2). The exposed photosensitive application film 103 includes an exposed portion 103a and an unexposed portion.

A known method can be used for the exposure processing. A light beam having wavelengths in the range of 1 nm to 600 nm can be used as a light source. Specifically, a low-pressure mercury lamp, a high-pressure mercury lamp, an ultra-high-pressure mercury lamp, a KrF excimer laser (wavelength 248 nm), an ArF excimer laser (wavelength 193 nm), an EUV beam (wavelength 13.5 nm), or the like can be used. The exposure amount can be adjusted according to the type and amount of the photoinduced compound to be used, the manufacturing process, and the like, and is not particularly limited, but may be about 1 to 10,000 mJ/cm², preferably about 10 to 5,000 mJ/cm².

After the exposure, post-exposure heating can be performed before the development step, if necessary. The temperature of the post-exposure heating is preferably 60° C. to 180° C., and the time of the post-exposure heating is preferably 30 seconds to 10 minutes.

### [Third Step]

Next, developing the exposed photosensitive application film 103 obtained in the second step removes the portions other than the exposed portion 103a, and a film having a desired pattern (hereinafter, sometimes referred to as the “patterned film”) 107 can be formed (step S3). Although FIG. 1 is diagram illustrating the method of manufacturing the negative patterned cured film, in the case where the positive patterned cured film is obtained, the exposed portion 103a is removed by developing, and the photosensitive application film 103, which is an unexposed portion shielded by the light-shielding plate 105, becomes the patterned film 107. The photoacid generator is used as the photoinduced compound (D), and the negative patterned cured film is obtained when X in the general formula (1a) is a hydrogen atom, and the positive patterned cured film is obtained when X is an acid-labile group.

Development is performed to form a pattern by dissolving and washing and removing the unexposed portions or exposed portions using an alkaline solution as a developer.

The developer to be used is not particularly limited as long as it can remove a desired photosensitive application film by a predetermined development method. Specific examples include alkali aqueous solutions using inorganic alkalis, primary amines, secondary amines, tertiary amines, alcohol amines, quaternary ammonium salts, and mixtures thereof.

More specific examples include alkaline aqueous solutions such as potassium hydroxide, sodium hydroxide, ammonia, ethylamine, diethylamine, triethylamine, triethanolamine, and tetramethylammonium hydroxide (abbreviation: TMAH). Among them, TMAH aqueous solution is preferably used, and in particular, TMAH aqueous solution of 0.1% by mass or more and 5% by mass or less, more preferably 2% by mass or more and 3% by mass or less is preferably used.

A known method such as an immersion method, a paddle method, or a spray method can be used as the development method, and the development time may be 0.1 minutes or more and 3 minutes or less. In addition, it is preferably 0.5 minutes or more and 2 minutes or less. Thereafter, the desired patterned film 107 can be formed on the substrate 101 by washing, rinsing, drying, or the like as necessary.

In addition, bleaching exposure is preferably performed after forming the patterned film 107. The purpose of the bleaching exposure is to improve the transparency of the finally obtained patterned cured film 111 by photolyzing the photoinduced compound remaining in the patterned film 107. The bleaching exposure can be performed in the same manner as in the second step.

### [Fourth Step]

Next, the patterned film (including the bleached-exposed patterned film) 107 obtained in the third step is subjected to a heat treatment to obtain the final patterned cured film 111 (step S4). The heat treatment makes it possible to condense the alkoxy group or the silanol group remaining as unreacted groups in the polysiloxane compound in the film. In addition, in the case where the photoinduced compound or photodegradation products of the photoinduced compound remain, they can be removed by thermal decomposition.

The heating temperature at this time is preferably 80° C. or more and 400° C. or less, and more preferably 100° C. or more and 350° C. or less. The heat treatment time may be 1 minute or more and 90 minutes or less, preferably 5 minutes or more and 60 minutes or less. Setting the heating temperature within the above range sufficiently proceeds the condensation reaction, the curing reaction, the thermal decomposition of the photoinduced compound or the photodegradation product of the photoinduced compound, and the desired chemical solution resistance, heat resistance, and transparency can be obtained. In addition, it is possible to suppress thermal decomposition of the polysiloxane compound constituting the patterned cured film 111 and cracks of the film to be formed, and it is possible to obtain a film having good adhesion to the substrate 101. The desired patterned cured film 111 can be formed on the substrate 101 by the heat treatment.

### [Optical Member]

The cured film described above is adjusted to a desired refractive index, and can be used as various lenses such as an anti-reflective film and a microlens, an optical waveguide, a light-shielding film, or a flattening film. In addition, the antireflection film and the various lenses such as a microlens, the optical waveguide, the light-shielding film, or the flattening film can be used for solid-state image sensors or a display device.

Examples of the electronic device having the solid-state image sensor include a video camera, a digital camera, a camera-equipped mobile phone, a copier, a gaming machine, and an automatic door.

Examples of the imaging device having the solid-state image sensor include an endoscopic camera, a microscope, a medical camera utilizing light reception of infrared light, an in-vehicle camera, a surveillance camera, a person authentication camera, and an industrial camera.

Examples of the display device include liquid crystal displays, organic EL displays, quantum-dot displays, and micro LED displays.

### EXAMPLES

Hereinafter, although the present invention will be described in more detail with reference to examples, the present invention is not limited to the following examples unless the gist thereof is exceeded.

In the examples, unless otherwise indicated, some compounds are designated as follows.
Ph-Si: phenyltriethoxysilane
Me-Si: methyltriethoxysilane
KBM-303: 2-(3,4-epoxycyclohexyl)ethyltrimethoxysilane manufactured by Shin-Etsu Chemical Co., Ltd
KBM-5103: 3-acryloxypropyltrimethoxysilane manufactured by Shin-Etsu Chemical Co., Ltd
PGMEA: Propylene glycol monomethyl ether acetate
HFA-Si: a compound represented by the following chemical formula

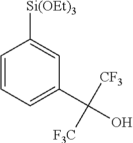

Equipment used for various measurements and measurement conditions will be described.

### [Weight Average Molecular Weight Measurement]

The weight average molecular weight (Mw) of the polysiloxane compound and the polymer described later was measured as follows. A high-speed GPC device manufactured by Tosoh Corporation, device name: HLC-8320GPC, TSKgel SuperHZ2000 manufactured by Tosoh Corporation as a column, and tetrahydrofuran (THF) as a solvent were used and measured in terms of polystyrene.

### [Solid Content Concentration Measurement]

Solid content concentrations of the polysiloxane and polymer solutions and the metal oxide solutions were determined by the following methods. 1.0 g of the solution was weighed into an aluminum cup and heated at 200° C. for 30 minutes using a hot plate to evaporate the solvent. The solid content remaining in the aluminum cup after heating was weighed to determine the solid content concentration in the solution.

### [Refractive Index Measurement]

The n-value (refractive index) in 633 nm was measured using a prism coupler device manufactured by Metricon Corporation, device name: 2010/M.

### [Evaluation of Film Formability]

The film formation unevenness and cracks on the cured film obtained from the prepared application liquid were visually evaluated. Those having no unevenness on the whole are defined as good (O), and those having film formation unevenness, and cracks are defined as defective (X).

### [Evaluation of Metal Oxide Particle Dispersion Stability]

The solution of the prepared application liquid was subjected to a centrifugal separator (manufactured by Koki Holdings Co., Ltd., CF16RN) at 15,000 rpm for 5 minutes at room temperature, and the dispersion stability of the fine metal oxide particles in the solution was visually confirmed. If there was no precipitate in the centrifuge tube, it was good (O), and if there was a precipitate, it was defective (X).

### Synthesis Example 1: Synthesis of HFA-Si

HFA-Si was synthesized in a known method according to International Patent Publication No. 2019/167770.

### Synthesis Example 2: Synthesis of Polysiloxane Compound 1 (HFA-Si/Ph-Si/KBM-303=1/8/1 Composition (Mole Ratio)

10.0 g (23.8 mmol) of HFA-Si, 45.8 g (190 mmol) of Ph-Si, 5.9 g (23.4 mmol) of KBM-303, 13.5 g (750 mmol) of pure water, and 1.7 g (28.3 mmol) of acetic acid were added to the reaction vessel, and the reaction was carried out at 40° C. for 1 hour, 70° C. for 1 hour, and 100° C. for 2 hours, and then 40 g of cyclohexanone was further added and the reaction was carried out at 130° C. for 2 hours.

After the reaction, the mixture was slowly cooled to room temperature, 30 g of pure water was added, and washing with water was repeated twice, and cyclohexanone was removed from the obtained organic layer using an evaporator to obtain 50 g (yield: 100%) of a polysiloxane compound 1 with a solid content concentration of 33% by mass. The weight average molecular weight Mw determined by GPC measurement was 1,600.

### Synthesis Example 3: Synthesis of Polysiloxane Compound 2 (HFA-Si/Ph-Si/KBM-303/KBM-5103=1/7/1/1 Composition (Mole Ratio)

5.0 g (11.9 mmol) of HFA-Si, 20.0 g (83.3 mmol) of Ph-Si, 2.9 g (11.9 mmol) of KBM-303, 2.8 g (11.9 mmol) of KBM-5103, 6.7 g (375 mmol) of pure water, and 0.8 g (3.6 mmol) of acetic acid were added to the reaction vessel, and the mixture was allowed to react at 40° C. for 1 hour, 70° C. for 1 hour, and 100° C. for 4 hours.

After the reaction, the mixture was slowly cooled to room temperature, 75 g of cyclohexanone and 25 g of pure water were added, and washing with water was repeated twice, and cyclohexanone was distilled off from the obtained organic layer using an evaporator to obtain a 47 g (yield: 100%) of a polysiloxane compound 2 with a solid content concentration of 50% by mass. The weight average molecular weight Mw determined by GPC measurement was 2,460.

### Synthesis Example 4: Synthesis of Polysiloxane Compound 3 (HFA-Si/Silicate 40=2/8 Composition (Mole Ratio)

3.25 g (8 mmol) of HFA-Si, 1.81 g (101 mmol) of pure water, and 0.12 g (2.0 mmol) of acetic acid were added to the reaction vessel, and the mixture was heated to 40° C. and stirred for 1 hour. Thereafter, 4.77 g of silicate 40 (pentamer on average, manufactured by TAMA CHEMICALS CO., LTD.) (32 mmol [in terms of SiO₂ contained in silicate 40. (silicate 40 is about 6.4 mmol as a pentamer)]) and 4.81 g of ethanol were added, and the mixture was stirred at 75° C. for 4 hours.

After stirring, PGMEA was added, and water, acetic acid, solvents, by-product ethanol, and part of PGMEA were distilled off using a rotary evaporator under reduced pressure at 60° C., and filtered under reduced pressure to obtain 17 g of a solution of a polysiloxane compound 3 with a solid content concentration of 30% by mass. The weight average molecular weight Mw determined by GPC measurement was 3,000.

### Synthesis Example 5: Synthesis of Polysiloxane Compound 4 (HFA-Si)

10.0 g (24.6 mmol) of HFA-Si, 1.4 g (78 mmol) of pure water, and 0.04 g (0.7 mmol) of acetic acid were added to the reaction vessel, and the reaction was carried out at 40° C. for 1 hour, 70° C. for 1 hour, and 100° C. for 4 hours.

After the reaction, the mixture was slowly cooled to room temperature, 30 g of cyclohexanone and 10 g of pure water were added, and washing with water was repeated twice, and cyclohexanone was distilled off from the obtained organic layer using an evaporator to obtain 5 g of a polysiloxane compound 4 with a solid content concentration of 73% by mass. The weight average molecular weight Mw determined by GPC measurement was 2,060.

### Synthesis Example 6: Synthesis of Polysiloxane Compound 5 (Ph-Si)

20 g (80.5 mmol) of Ph-Si, 4.6 g (253.5 mmol) of pure water, and 0.14 g (2.4 mmol) of acetic acid were added to the reaction vessel, and the reaction was carried out at 40° C. for 1 hour, 70° C. for 1 hour, and 100° C. for 4 hours.

After the reaction, the mixture was slowly cooled to room temperature, 60 g of cyclohexanone and 20 g of pure water were added, and washing with water was repeated twice, and cyclohexanone was distilled off from the obtained organic layer using an evaporator to obtain 13 g of a polysiloxane compound 5 with a solid content concentration of 73% by mass. The weight average molecular weight Mw determined by GPC measurement was 6,880.

### Synthesis Example 7: Synthesis of Polysiloxane Compound 6 (Ph-Si/Silicate 40=2/8 Composition (Mole Ratio)

1.92 g (8 mmol) of Ph-Si, 0.90 g (50 mmol) of pure water, and 0.12 g (2.0 mmol) of acetic acid were added to the reaction vessel, and the mixture was heated to 40° C. and stirred for 1 hour. Thereafter, 4.77 g of silicate 40 (pentamer on average, manufactured by TAMA CHEMICALS CO., LTD.) (32 mmol [in terms of SiO₂ contained in silicate 40. (silicate 40 is about 6.4 mmol as a pentamer)]) and 4.81 g of ethanol were added, and the mixture was stirred at 75° C. for 4 hours.

After stirring, PGMEA was added, and water, acetic acid, solvents, by-product ethanol, and part of PGMEA were distilled off using a rotary evaporator under reduced pressure at 60° C., and filtered under reduced pressure to obtain 9 g of a solution of a polysiloxane compound 6 with a solid content concentration of 30 mass % by mass. The weight average molecular weight Mw determined by GPC measurement was 1,000.

### Synthesis Example 8: Synthesis of Polysiloxane Compound 7 (HFA-Si/Me-Si/KBM-303/KBM-5103=1/7/1/1 Composition (Mole Ratio))

2.03 g (5 mmol) of HFA-Si, 6.24 g (35 mmol) of Me-Si, 1.23 g (5 mmol) of KBM-303, 1.17 g (5 mmol) of KBM-5103, 2.84 g (158 mmol) of pure water, and 0.15 g (2.5 mmol) of acetic acid were added to the reaction vessel, and the mixture was allowed to react at 75° C. for 24 hours.

After the reaction, the mixture was slowly cooled to room temperature, and 10.67 g of IPE and 10.67 g of pure water were added, washing with water was repeated twice, PGMEA was added to the obtained organic layer, and part of the water, IPE, and PGMEA was distilled off using a rotary evaporator under reduced pressure at 60° C. to obtain 18.5 g of a polysiloxane compound 7 with a solid content concentration of 30%. The weight average molecular weight Mw determined by GPC measurement was 1,710.

### [Solvent Replacement of Metal Oxide Particles]

### Solvent Replacement Example 1: Solvent Replacement of ELCOM TGX-63A

A solvent of titania sol (ELCOM TGX-63A, manufactured by JGC Catalysts and Chemicals Ltd., primary particle size: 10 nm) as metal oxide particles was replaced from MIBK with cyclohexanone. 30 g of MIBK sol of titania sol (solid content concentration of 20%) and 20 g of cyclohexanone were added to a 100 ml eggplant flask, and MIBK was removed using a rotary evaporator under reduced pressure at 50° C. The obtained titania sol cyclohexanone solution (M1) was measured to have a solid content concentration of 28%.

### Solvent Replacement Example 2: Solvent Replacement of Zirconeo-Ck

The solvent of zirconia sol (Zirconeo-Ck, manufactured by ITEC Co., Ltd, primary particle size: 10 nm) as the metal-oxide particles was replaced from MEK/methanol=80/20 with cyclohexanone. 30 g of zirconia sol/methanol=80/20 sol (solid content concentration of 30%) and 20 g of cyclohexanone were added to a 100 ml eggplant flask, and MEK and methanol were removed using a rotary evaporator under reduced pressure at 50° C. The obtained zirconia sol cyclohexanone solution (M2) was measured to have a solid content concentration of 31%.

### Solvent Replacement Example 3: Solvent Replacement of THRULYA 4110

The solvent of the hollow silica sol (THRULYA 4110, manufactured by JGC Catalysts and Chemicals Ltd., average primary particle size: 60 nm) as the metal-oxide particles was replaced from IPA with cyclohexanone. 30 g of an IPA sol of hollow silica sol (solid content concentration of 20.5%) and 20 g of cyclohexanone were added to a 100 ml eggplant flask, and IPA was removed using a rotary evaporator under reduced pressure at 50° C. The obtained hollow silica sol cyclohexanone (M3) was measured to have a solid content concentration of 26%.

### Example 1

An application liquid 1 was prepared by mixing and stirring at the ratio of the application liquid shown in Table 1. No sediment was visually observed in the application liquid 1 immediately after stirring.

The application liquid 1 was filtered through a filter with a pore size of 0.45 μm, coated on a 4-inch silicon wafer at a rotational speed of 500 rpm using a spin coater, and then heated using a hot plate at 100° C. for 3 minutes to form a cured film 1 with a thickness of 2 μm.

### Examples 2 to 15

Application liquids 2 to 15 were prepared by mixing and stirring at the ratios shown in Table 1 in the same manner as in Example 1, and cured films 2 to 15 were formed in the same manner as in the cured film 1 using each application liquid obtained. No sediment was visually observed in any of the application liquids 2 to 15 immediately after stirring.

### Example 1-1

The application liquid 1 was filtered through a filter with a pore size of 0.45 μm, coated on a 4-inch silicon wafer at a rotational speed of 500 rpm using a spin coater, and then heated at 100° C. for 3 minutes using a hot plate, and then heated at 230° C. for 3 minutes to form a cured film of Example 1-1 with a thickness of 2 μm.

### Examples 2-1 and 3-1

In the same manner as in Example 1-1, a cured film of Example 2-1 with a thickness of 2 μm and a cured film of Example 3-1 were formed using the application liquid 2 and the application liquid 3, respectively.

### Comparative Examples 1 to 7

Application liquids 16 to 22 were prepared by mixing and stirring at the ratios of the application liquid shown in Table 1. The obtained application liquids 16, 17, and 19 to 22 were used to form cured films of Comparative Examples 1, 2, and 4 to 7 in the same manner as the cured film 1. An application liquid 18 was used as Comparative Example 3. No sediment was visually observed in any of the application liquids 16 to 22 immediately after stirring. Table 2 shows the results.

TABLE 1

| | | | Metal | |
|---|---|---|---|---|
| | Application | | oxide | |
| Examples | liquid | Polysiloxane | particles | Solvent |
| Example 1 | Application | Compound 1 | M1 (5) | Cyclohexanone |
| | liquid 1 | (27) | | (68) |
| Example 2 | Application | Compound 1 | M1 (10) | Cyclohexanone |
| | liquid 2 | (21) | | (69) |
| Example 3 | Application | Compound 1 | M2 (5) | Cyclohexanone |
| | liquid 3 | (27) | | (68) |
| Example 4 | Application | Compound 1 | M2 (10) | Cyclohexanone |
| | liquid 4 | (21) | | (69) |
| Example 5 | Application | Compound 1 | M2 (14) | Cyclohexanone |
| | liquid 5 | (17) | | (69) |
| Example 6 | Application | Compound 1 | M2 (25) | Cyclohexanone |
| | liquid 6 | (6) | | (69) |
| Example 7 | Application | Compound 2 | M1 (5) | Cyclohexanone |
| | liquid 7 | (27) | | (68) |
| Example 8 | Application | Compound 2 | M1 (10) | Cyclohexanone |
| | liquid 8 | (21) | | (69) |
| Example 9 | Application | Compound 2 | M1 (14) | Cyclohexanone |
| | liquid 9 | (17) | | (69) |
| Example 10 | Application | Compound 2 | M2 (5) | Cyclohexanone |
| | liquid 10 | (27) | | (68) |
| Example 11 | Application | Compound 2 | M2 (25) | Cyclohexanone |
| | liquid 11 | (6) | | (69) |
| Example 12 | Application | Compound 3 | M3 (5) | Cyclohexanone/ |
| | liquid 12 | (27) | | PGMEA(14/54) |
| Example 13 | Application | Compound 3 | M3 (10) | Cyclohexanone/ |
| | liquid 13 | (21) | | PGMEA(28/41) |
| Example 14 | Application | Compound 3 | M3 (13) | Cyclohexanone/ |
| | liquid 14 | (17) | | PGMEA(37/33) |
| Example 15 | Application | Compound 4 | M1 (10) | Cyclohexanone |
| | liquid 15 | (21) | | (69) |
| Comparative | Application | Compound 5 | — | Cyclohexanone |
| Example 1 | liquid 16 | (30) | | (70) |
| Comparative | Application | Compound 5 | M1 (10) | Cyclohexanone |
| Example 2 | liquid 17 | (21) | | (69) |
| Comparative | Application | Compound 6 | M3 (10) | Cyclohexanone/ |
| Example 3 | liquid 18 | (21) | | PGMEA(28/41) |
| Comparative | Application | Compound 1 | — | Cyclohexanone |
| Example 4 | liquid 19 | (30) | | (70) |
| Comparative | Application | Compound 2 | — | Cyclohexanone |
| Example 5 | liquid 20 | (30) | | (70) |
| Comparative | Application | Compound 3 | — | PGMEA (70) |
| Example 6 | liquid 21 | (30) | | |
| Comparative | Application | Compound 4 | — | Cyclohexanone |
| Example 7 | liquid 22 | (30) | | (70) |

Numbers in parentheses are weight ratios. Calculated from solid content concentration.

The film formability of the cured films obtained in Comparative Example 7, Example 15, and Comparative Examples 1 and 2 was evaluated. The same spin coating conditions as described in Example 1 were used to evaluate the film formability. Table 2 shows the results.

TABLE 2

| | Evaluation of film formability |
|---|---|
| Comparative | ◯ |
| Example 7 | |
| Example 15 | ◯ |
| Comparative | ◯ |
| Example 1 | |
| Comparative | X |
| Example 2 | |

◯: No comet-like unevenness or cracks are visually observed.
X: Comet-like unevenness and cracks are visually observed.

As shown in Table 2, in the application liquid using the polysiloxane compound 4 containing the HFIP group, a uniform film was obtained regardless of the presence or absence of the addition of a metal oxide fine particle M1 (presence: Example 15, absence: Comparative Example 7). On the other hand, in the application liquid using the polysiloxane compound 5 containing no HFIP group, a uniform film can be obtained in Comparative Example 1 in which the metal oxide fine particle M1 is not added. On the other hand, in Comparative Example 2 in which the metal oxide fine particle M1 was added, comet-like unevenness and cracks occurred, and a uniform film could not be obtained. Although the details are unknown, it is considered that the 2-hydroxy-1,1,1,3,3,3-hexafluoroisopropyl group (HFIP group) in the polysiloxane compound enhances compatibility with the metal oxide fine particles.

The application liquid 13 obtained in Example 13 and the application liquid 18 obtained in Comparative Example 3 were subjected to evaluation of dispersion stability of the metal oxide by centrifugation. Table 3 shows the results.

TABLE 3

| | Dispersion stability evaluation |
|---|---|
| Example 13 | ◯ |
| Comparative | X |
| Example 3 | |

◯: No precipitate is visually observed.
X: The precipitate is visually observed.

As shown in Table 3, in Example 13 (application liquid 13) using the polysiloxane compound 3 containing the HFIP group, the application liquid remained dispersed even after the centrifugation, and no precipitate was found in the lower part of the centrifuge tube. After that, even after being left at room temperature for 2 weeks, no precipitate was observed, and the dispersion state was maintained. On the other hand, in Comparative Example 3 (application liquid 18) using the polysiloxane compound 6 containing no HFIP group, a precipitate was observed in the lower portion of the centrifuge tube after the centrifugation. As in the case of evaluating the film formability, although the details are unknown, it is considered that the 2-hydroxy-1,1,1,3,3,3-hexafluoroisopropyl group (HFIP group) in the polysiloxane compound enhances the compatibility with the metal oxide fine particles.

### Example 16

3.25 g (8 mmol) of HFA-Si, 2.72 g (8 mmol) of tetra(n-butoxy)titanium, and 0.19 g (3.2 mmol) of acetic acid were added to the reaction vessel, and the mixture was stirred at room temperature for 24 hours, 3.68 g of ethanol was further added and stirred for 5 minutes. After that, 0.14 g (8 mmol) of pure water was further added and stirred, and it was confirmed that the solution was visually transparent and maintained in a dispersed state without changing from those before the pure water was added. 0.29 g (3.2 mmol) of 69% nitric acid was then added and stirred for an additional 24 hours. The reaction solution finally obtained was also visually transparent and uniform in that the dispersed state was maintained.

Then, 10 g of PGMEA was added and evaporated at 50° C. to obtain 7.9 g of an application liquid 23 which is a uniform solution. The weight average molecular weight Mw determined by GPC measurement was 1,310.

### Comparative Example 8

1.92 g (8 mmol) of Ph-Si, 2.72 g (8 mmol) of tetra(n-butoxy)titanium, and 0.19 g (3.2 mmol) of acetic acid were added to the reaction vessel, and the mixture was stirred at room temperature for 24 hours, 3.68 g of ethanol was further added and stirred for 5 minutes, and 0.14 g (8 mmol) of pure water was added to produce a white precipitate.

From the results of Example 16 and Comparative Example 8, although the details are unknown, it is considered that the HFIP group enhances the compatibility with alkoxy titanium at the time of hydrolysis polymerization.

In summary, Examples 1 to 15 in which the metal oxide fine particles (component (A-1)) are used as the component (A) are considered to be effective as stabilizers in which the HFIP group in the polysiloxane compound including the constituent unit represented by the general formula (1) enhances compatibility with the component (A).

In addition, it is considered that in Example 16 using a polymer obtained by the hydrolysis polycondensation reaction of alkoxy titanium, the constituent unit represented by the general formula (1-A) and the constituent unit represented by the general formula (1) are uniformly present in the polymer, and therefore, the precipitation can be suppressed.

### [Negative Patterning Test]

### Example 17

10 g of the polysiloxane compound 7 (HFA-Si/Me-Si/KBM-303/KBM-5103=1/7/1/1 composition) obtained in Synthesis Example 8 was weighed, and 0.016 g of Irgacure 290 (manufactured by BASF), which is a photoacid generator, was added and dissolved, and 1.59 g of THRULYA 4110 (20.5 wt % IPA solution, manufactured by JGC Catalysts and Chemicals Ltd.), which is the hollow silica sol, was added to prepare a photosensitive resin composition 1 with a filler-added content of 10% with respect to the polymer solid content.

### Example 18

g of the polysiloxane compound 7 (HFA-Si/Me-Si/KBM-303/KBM-5103=1/7/1/1 composition) obtained in Synthesis Example 8 was weighed, and 0.016 g of Irgacure 290 (manufactured by BASF), which is a photoacid generator, was added and dissolved, 3.17 g of THRULYA 4110 (20.5 wt % IPA solution, manufactured by JGC Catalysts and Chemicals Ltd.), which is the hollow silica sol, was added to prepare a photosensitive resin composition 2 with a filler-added content of 20% with respect to the polymer solid content.

### Example 19

10 g of the polysiloxane compound 7 (HFA-Si/Me-Si/KBM-303/KBM-5103=1/7/1/1 composition) obtained in Synthesis Example 8 was weighed, and 0.016 g of Irgacure 290 (manufactured by BASF), which is a photoacid generator, was added and dissolved, 4.76 g of THRULYA 4110 (20.5 wt % IPA solution, manufactured by JGC Catalysts and Chemicals Ltd.), which is the hollow silica sol, was added to prepare a photosensitive resin composition 3 with a filler-added content of 30% with respect to the polymer solid content.

### Example 20

10 g of the polysiloxane compound 7 (HFA-Si/Me-Si/KBM-303/KBM-5103=1/7/1/1 composition) obtained in Synthesis Example 8 was weighed, and 0.016 g of Irgacure 290 (manufactured by BASF), which is a photoacid generator, was added and dissolved, 6.34 g of THRULYA 4110 (20.5 wt % IPA solution, manufactured by JGC Catalysts and Chemicals Ltd., which is the hollow silica sol, to prepare a photosensitive resin composition 4 with a filler-added content of 40% with respect to the polymer solid content.

### [Development Test]

The photosensitive resin composition obtained in Example 17 was coated on a 4-inch-diameter and 525-μm-thick silicon wafer manufactured by SUMCO CORPORATION by spin-coating (rotational speed 500 rpm). Thereafter, the silicon wafer was heat-treated on a hot plate at 100° C. for 1 minute to obtain a photosensitive resin film 1.

The obtained photosensitive resin film 1 was irradiated with light from a high-pressure mercury lamp at 155 mJ/cm² (wave-length 365 nm) via a photomask using an exposure device. Thereafter, a heat treatment was performed at 100° C. for 30 seconds on a hot plate. After that, it was developed by immersion in 2.38% by mass of a TMAH aqueous solution for 10 seconds, and washed by immersion in pure water for 30 seconds. After the washing, bleaching exposure was performed at 300 mJ/cm² (the same light source as at the time of exposure), and baked in an oven at 230° C. for 1 hour in the atmosphere to obtain a patterned cured film with a thickness of 2.6 μm.

A photosensitive resin film was prepared in the same manner as in Example 17 using the photosensitive resin composition obtained in Example 18, and then irradiated with light at 385 mJ/cm² via a photomask using the exposure device, and thereafter a patterned cured film with a thickness of 2.8 μm was obtained in the same manner as in Example 17.

A photosensitive resin film was prepared in the same manner as in Example 17 using the photosensitive resin composition obtained in Example 19, and then irradiated with light at 655 mJ/cm² via a photomask using the exposure device, and thereafter a patterned cured film with a thickness of 2.7 μm was obtained in the same manner as in Example 17.

A photosensitive resin film was prepared in the same manner as in Example 17 using the photosensitive resin composition obtained in Example 20, and then irradiated with light at 1,014 mJ/cm² via a photomask using the exposure device, and thereafter a patterned cured film 4 with a thickness of 2.8 μm was obtained in the same manner as in Example 17.

As a result of confirming the obtained patterned cured film with an optical microscope, it was found that a negative patterned cured film was obtained when the development treatment was performed using the photosensitive resin compositions of Examples 17 to 20.

### [Refractive Index Measurement]

The refractive index measurement was performed on the cured films obtained in Examples 1 to 14, Example 1-1, Example 2-1, Example 3-1, and Comparative Examples 4 to 6, and the patterned cured films obtained in Examples 17 to 20. The measurement results are shown in Table 4 and Table 5.

TABLE 4

| | Application liquid | Refractive index |
|---|---|---|
| Example 1 | Application liquid 1 | 1.57 |
| Example 1-1 | Application liquid 1 | 1.57 |
| Example 2 | Application liquid 2 | 1.59 |
| Example 2-1 | Application liquid 2 | 1.60 |
| Example 3 | Application liquid 3 | 1.56 |
| Example 3-1 | Application liquid 3 | 1.56 |
| Example 4 | Application liquid 4 | 1.57 |
| Example 5 | Application liquid 5 | 1.59 |
| Example 6 | Application liquid 6 | 1.63 |
| Example 7 | Application liquid 7 | 1.57 |
| Example 8 | Application liquid 8 | 1.58 |
| Example 9 | Application liquid 9 | 1.62 |
| Example 10 | Application liquid 10 | 1.57 |
| Example 11 | Application liquid 11 | 1.62 |
| Example 12 | Application liquid 12 | 1.39 |
| Example 13 | Application liquid 13 | 1.37 |
| Example 14 | Application liquid 14 | 1.33 |
| Comparative Example 4 | Application liquid 19 | 1.54 |
| Comparative Example 5 | Application liquid 20 | 1.54 |
| Comparative Example 6 | Application liquid 21 | 1.44 |

TABLE 5

| | Application liquid | Refractive index |
|---|---|---|
| Example 17 | Photosensitive resin composition 1 | 1.43 |
| Example 18 | Photosensitive resin composition 2 | 1.41 |
| Example 19 | Photosensitive resin composition 3 | 1.40 |
| Example 20 | Photosensitive resin composition 4 | 1.39 |

It was found that the refractive index of the cured film of Example 1 containing the metal oxide fine particle M1 was 1.57, and the refractive index of the cured film of Example 2 was 1.59, which was higher than the refractive index of 1.54 of the cured film of Comparative Example 4 containing no metal oxide fine particle M1.

It was found that the refractive index of the cured film of Example 3 containing a metal oxide fine particle M2 was 1.56, the refractive index of the cured film of Example 4 was 1.57, the refractive index of the cured film of Example 5 was 1.59, and the refractive index of the cured film of Example 6 was 1.63, which was higher than the refractive index of 1.54 of the cured film of Comparative Example 4 containing no metal oxide fine particle M2.

It was found that the refractive index of the cured film of Example 7 containing the metal oxide fine particle M1 was 1.57, the refractive index of the cured film of Example 8 was 1.58, and the refractive index of the cured film of Example 9 was 1.62, which was higher than the refractive index of 1.54 of the cured film of Comparative Example 5 containing no metal oxide fine particle M1.

It was found that the refractive index of the cured film of Example 10 containing the metal oxide fine particle M2 was 1.57, and the refractive index of the cured film of Example 11 was 1.62, which was higher than the refractive index of 1.54 of the cured film of Comparative Example 5 containing no metal oxide fine particle M2.

It was found that the refractive index of the cured film of Example 12 containing the metal oxide fine particle M3 was 1.39, the refractive index of the cured film of Example 13 was 1.37, and the refractive index of the cured film of Example 14 was 1.33, which was lower than the refractive index of 1.44 of the cured film of Comparative Example 6 containing no metal oxide fine particle M3.

The refractive index values of the cured film of Example 1-1, the cured film of Example 2-1, and the cured film of Example 3-1 obtained by heating at 230° C. for 3 minutes were substantially the same as the refractive index values of the cured film of Example 1, the cured film of Example 2, and the cured film of Example 3 obtained by heating at 110° C. for 3 minutes.

According to an embodiment of the present disclosure, an application liquid for an optical member in which metal fine particles are stably dispersed in an application liquid is provided. Alternatively, in an embodiment, an application liquid in which sedimentation or precipitation of a metal alkoxide is unlikely to occur is provided. Alternatively, in an embodiment, a polymer that can be used as an application liquid for an optical member, a cured film using an application liquid for an optical member, a photosensitive application liquid, a patterned cured film, an optical member, a solid image sensor, a display device, and a stabilizer for use in an application liquid are provided. Alternatively, a method for producing a stabilizer for use in an application liquid is provided. Alternatively, a method for producing a cured film, a patterned cured film, or a polymer having excellent optical properties is provided.

1. An application liquid for an optical member comprising:
a component (A) consisting of metal fine particles (A-1) and/or a metal compound (A-2) including a constituent unit represented by a following general formula (1-A);
a stabilizer (B) consisting of a polysiloxane compound including a constituent unit represented by a following general formula (1); and
a solvent (C),
[(R¹)_{b}MO_{c/2}] (1-A)
[(R²)_{d}(R³)ₑ(OR⁴)_{f}SiO_{g/2}] (1)
wherein, in the general formula (1-A), M is at least one selected from a group consisting of Ti, Zr, Al, Hf, In, and Sn,
each R¹ is independently selected from a group consisting of a hydrogen atom, hydroxy group, halogen group, an alkoxy group having a carbon number of 1 or more and 5 or less, an alkyl group having a carbon number of 1 or more and 5 or less, a phenyl group, and a fluoroalkyl group having a carbon number of 1 or more and 10 or less,
b is a number of 0 or more and less than 4, c is a number more than 0 and 4 or less, and b+c=3 or 4,
in the general formula (1), R² is a group represented by a following general formula (1a), 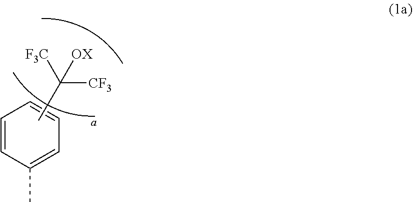
in the general formula (1a), X is a hydrogen atom or an acid-labile group,
a is a number of 1 to 5, and a broken line represents a bond,
each R³ is independently selected from a group consisting of a hydrogen atom, an alkyl group having a carbon number of 1 or more and 5 or less, a phenyl group, and a fluoroalkyl group having a carbon number of 1 or more and 10 or less, and each R⁴ is independently a hydrogen atom or an alkyl group having a carbon number of 1 or more and 5 or less,
d is a number of 1 or more and 3 or less, e is a number of 0 or more and 2 or less, f is a number of 0 or more and less than 3, g is a number more than 0 and 3 or less, and d+e+f+g=4.

2. The application liquid for the optical member according to claim 1, wherein the metal fine particles (A-1) include at least one selected from a group consisting of Si, Ti, Zr, Al, Mg, Hf, In, and Sn.

3. The application liquid for the optical member according to claim 1, wherein the metal fine particles (A-1) are at least one selected from a group consisting of silica, hollow silica, titanium oxide, zirconium oxide, magnesium fluoride, indium tin oxide, antimony-doped indium oxide, and hafnium oxide.

4. The application liquid for the optical member according to claim 1, wherein the group represented by the general formula (1a) is a group represented by any of following general formulas (1aa) to (1ad), 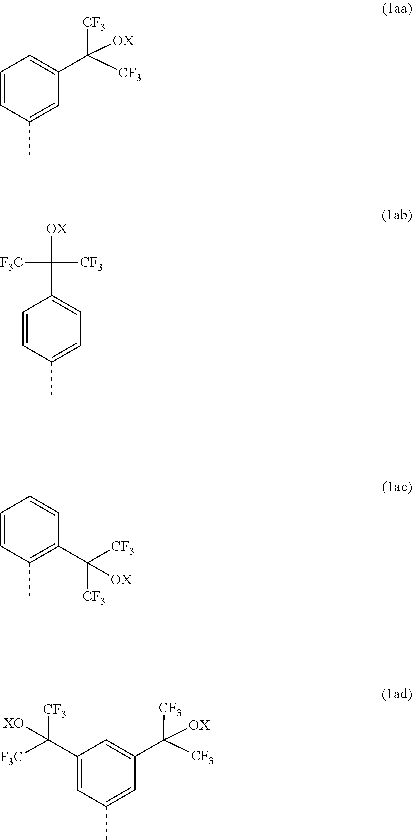
wherein, in the formulas (1aa) to (1ad), the definitions of X and the broken line are the same as the definitions in the general formula (1a).

5. The application liquid for an optical member according to claim 1, wherein the polysiloxane compound includes a constituent unit represented by a following general formula (2) and/or a following general formula (3),
[(R⁵)ₕ(R⁶)ᵢSiO_{j/2}] (2)
[(R⁷)ₖSiO_{l/2}] (3)
wherein, in the general formula (2), R⁵ is a substituent selected from monovalent organic groups having a carbon number of 1 or more and 30 or less substituted by any of an epoxy group, oxetane group, acryloyl group, methacryloyl group and lactone group, R⁶ is a hydrogen atom, or a substituent selected from a group consisting of a halogen group, an alkyl group having a carbon number of 1 or more and 5 or less, a phenyl group, hydroxy group, an alkoxy group having a carbon number of 1 or more and 3 or less, and a fluoroalkyl group having a carbon number of 1 or more and 10 or less,
h is a number of 1 or more and 3 or less, i is a number of 0 or more and less than 3, j is a number more than 0 and 3 or less, and h+i+j=4,
when there is a plurality of R⁵ and R⁶, each of them is independently selected from any of the substituents,
in the general formula (3), R⁷ is a substituent selected from a group consisting of a halogen group, alkoxy group, and a hydroxy group, and
k is a number of 0 or more and less than 4, 1 is a number more than 0 and 4 or less, and k+1=4.

6. The application liquid for the optical member according to claim 5, wherein the monovalent organic group R⁵ is a group represented by any of following general formulas (2a), (2b), (2c), (3a), and (4a), 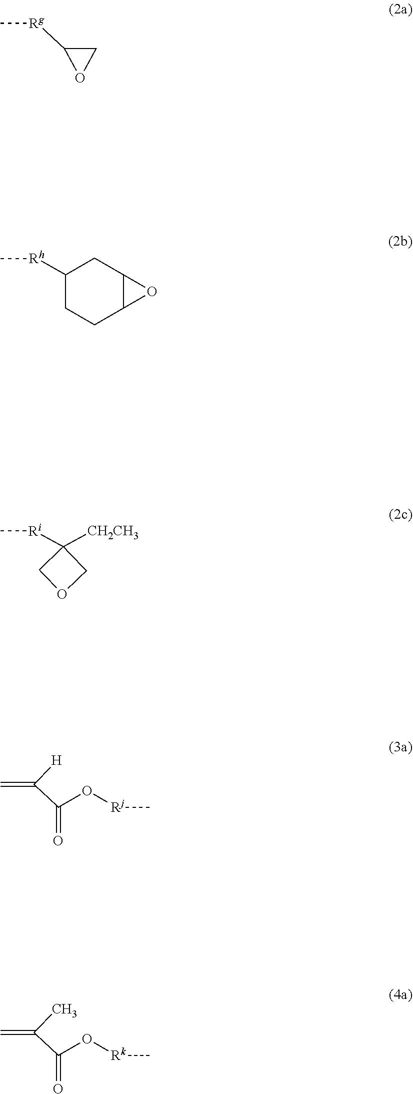
wherein, in the general formulas (2a), (2b), and (2c), each R^{g}, R^{h}, Rⁱ is independently a divalent linking group, and a broken line represents a bond, and
in the general formulas (3a) and (4a), each R^{j} and R^{k} is independently a divalent linking group, and a broken line represents a bond.

7. The application liquid for the optical member according to claim 5, wherein the constituent unit represented by the general formula (3) less than 5 mol % or more than 50 mol % is contained in the whole constituent unit of the polysiloxane compound represented by the general formula (1).

8. The application liquid for the optical member according to claim 1, wherein the solvent (C) includes at least one compound selected from a group consisting of propylene glycol monomethyl ether acetate, propylene glycol monomethyl ether, cyclohexanone, ethyl lactate, γ-butyrolactone, diacetone alcohol, diglyme, methyl isobutyl ketone, 3-methoxybutyl acetate, 2-heptanone, N,N-dimethylformamide, N,N-dimethylacetamide, N-methylpyrrolidone, glycols, glycol ethers and glycol ether esters.

9. A polymer comprising:
a constituent unit represented by a following general formula (1); and
a constituent unit represented by a general formula (1-A),
[(R¹)_{b}MO_{c/2}] (1-A)
[(R²)_{d}(R³)ₑ(OR⁴)_{f}SiO_{g/2}] (1)
wherein, in the general formula (1-A), M is at least one selected from a group consisting of Ti, Zr, Al, Hf, In, and Sn, each R¹ is independently selected from a group consisting of a hydrogen atom, hydroxy group, halogen group, an alkoxy group having a carbon number of 1 or more and 5 or less, an alkyl group having a carbon number of 1 or more and 5 or less, a phenyl group, and a fluoroalkyl group having a carbon number of 1 or more and 10 or less,
b is a number of 0 or more and less than 4, c is a number more than 0 and of 4 or less, and b+c=3 or 4,
in the general formula (1), R² is a group represented by a following general formula (1a), 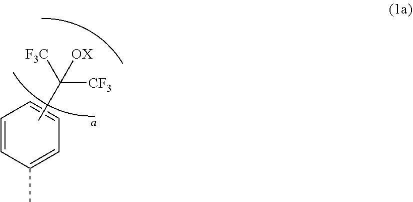
in the general formula (1a), X is a hydrogen atom or an acid-labile group,
a is a number of 1 to 5, and a broken line represents a bond,
each R³ is independently selected from a group consisting of a hydrogen atom, an alkyl group having a carbon number of 1 or more and 5 or less, a phenyl group, and a fluoroalkyl group having a carbon number of 1 or more and 10 or less, and each R⁴ is independently a hydrogen atom or an alkyl group having a carbon number of 1 or more and 5 or less,
d is a number of 1 or more and 3 or less, e is a number of 0 or more and 2 or less, f is a number of 1 or more and less than 3, g is a number more than 0 and 3 or less, and d+e+f+g=4.

10. An application liquid for the optical member according to claim 1, comprising:
the polymer according to claim 9; and
a solvent (C).

11. The application liquid for the optical member according to claim 10, wherein the solvent (C) includes at least one compound selected from a group consisting of propylene glycol monomethyl ether acetate, propylene glycol monomethyl ether, cyclohexanone, ethyl lactate, γ-butyrolactone, diacetone alcohol, diglyme, methyl isobutyl ketone, 3-methoxybutyl acetate, 2-heptanone, N,N-dimethylformamide, N,N-dimethylacetamide, N-methylpyrrolidone, glycols, glycol ethers and glycol ether esters.

12. The application liquid for the optical member according to claim 10, further comprising: metal fine particles.

13. A method for producing a cured film comprising:
A step of applying the application liquid for an optical member according to claim 1 on a substrate and heating the application liquid at a temperature of 80° C. or more and 350° C. or less.

14. A photosensitive application liquid comprising:
the application liquid for an optical member according to claim 1; and
a photoinduced compound (D).

15. The photosensitive application liquid according to claim 15, wherein the photoinduced compound (D) is at least one selected from a group consisting of naphthoquinonediazide, photoacid generator, photobase generator and photoradical generator.

16. A method for producing a patterned cured film comprising:
applying the photosensitive application liquid according to claim 14 on a substrate to form a photosensitive application film;
exposing the photosensitive application film through a photomask;
developing the photosensitive application film after exposure to form a patterned film; and
curing the patterned film by heating the patterned film to obtain the patterned cured film.

17. The method for producing the patterned cured film according to claim 16, wherein the photosensitive application film is exposed by irradiating a light beam having a wavelength of 1 nm or more and 600 nm or less through the photomask.

18. A method for producing a polymer, wherein the polymer is the polymer according to claim 9 obtained by hydrolytic polycondensing a silicon compound represented by a following general formula (1y) and a metal compound represented by a following general formula (1-2), 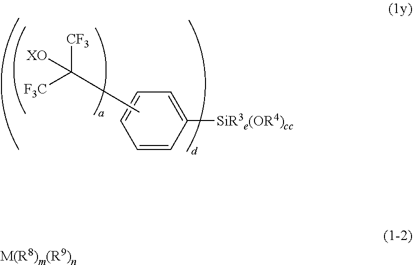
the polymer includes the constituent unit represented by the general formula (1); and the constituent unit represented by the general formula (1-A),
in the general formula (1y), each R³ is independently selected from a group consisting of a hydrogen atom, an alkyl group having a carbon number of 1 or more and 5 or less, a phenyl group, and a fluoroalkyl group having a carbon number of 1 or more and 10 or less, R⁴ is independently a hydrogen atom or an alkyl group having a carbon number of 1 or more and 5 or less, a is a number of 1 or more and 5 or less, d is a number of 1 or more and 3 or less, e is a number of 0 or more and 2 or less, cc is a number of 1 or more and 3 or less, and d+e+cc=4, X is a hydrogen atom or an acid-labile group,
in the general formula (1-2), M is at least one selected from a group consisting of Ti, Zr, Al, Hf, In and Sn, each R⁸ is independently selected from a group consisting of a hydrogen atom, hydroxy group, halogen group, an alkoxy group having a carbon number of 1 or more and 5 or less, an alkyl group having a carbon number of 1 or more and 5 or less, a phenyl group, and a fluoroalkyl group having a carbon number of 1 or more and 10 or less, R⁹ is an alkoxy group having a carbon number of 1 or more and 5 or less, or a halogen,
m is a number of 0 or more and 3 or less, n is a number of 1 or more and 4 or less, and m+n=3 or 4.

19. The method for producing the polymer according to claim 18, wherein a chelator is added to the metal compound represented by the general formula (1-2) at the time when hydrolytic polycondensing is performed and/or before the time.
